(19) United States
(12) Patent Application Publication
(10) Pub. No.: US 2014/0345843 A1
(43) Pub. Date: Nov. 27, 2014

(54) DYNAMIC THERMAL INTERFACE MATERIAL

(71) Applicants: Ewa S. Kirkor, Branford, CT (US); April Dawn Schricker, Palo Alto, CA (US); Saion K. Sinha, Fairfield, CT (US); Alexander Scheeline, Champaign, IA (US)

(72) Inventors: Ewa S. Kirkor, Branford, CT (US); April Dawn Schricker, Palo Alto, CA (US); Saion K. Sinha, Fairfield, CT (US); Alexander Scheeline, Champaign, IA (US)

(73) Assignee: Anchor Science LLC, Branford, CT (US)

(21) Appl. No.: 14/236,681

(22) PCT Filed: Aug. 3, 2012
(86) PCT No.: PCT/US12/49635

§ 371 Date: Aug. 11, 2014

Related U.S. Application Data
(60) Provisional application No. 61/514,715, filed on Aug. 3, 2011.

(51) Int. Cl. F28F 21/02; C09K 5/14; H05K 7/20

(52) U.S. Cl. CPC F28F 21/02; H05K 7/2039; C09K 5/14
USPC 165/185; 252/71

(57) ABSTRACT

Aspects of the invention provide compositions that include carbon nanotubes dispersed within nanographite particles, and that have useful thermal properties. Certain compositions have high thermal conductivities (e.g., high thermal conductivities at ambient temperature). Certain compositions have a temperature dependent thermal conductivity that reversibly increases with temperature. Certain compositions are useful for heat transfer and can be used as thermal interface material, for example, in the context of computer and/or power generating devices.

### RELATED APPLICATIONS

This application claims the benefit of U.S. Provisional Patent Application Ser. No. 61/514,715, filed Aug. 3, 2011, entitled “Dynamic Thermal Interface Material”, the contents of which are incorporated herein by reference.

### FIELD OF THE INVENTION

Aspects of the invention relate to the field of thermal interface materials, including nanoparticulate materials.

### BACKGROUND OF THE INVENTION

Typically natural heat dissipation from a powered device is insufficient, thus its temperature exceeds the allowable limit of the device. Thus, the ability to remove heat quickly from a powered or otherwise heated part is the key to the performance of the heated part (e.g., a processor, semiconductor, or other computer component). Heat transfer is typically managed by moving energy away from a power-dissipating part by conduction to a heat sink or an active cooling device, frequently through a thermal spreader, using thermal stacks and thermal interface materials (TIM). The effectiveness of a thermal stack depends on the thickness and bulk heat conductivity of the TIM, as well as the interfacial thermal resistance on contact surfaces between the TIM and components of the stack from which natural or forced convection can transfer the heat to the outside. Challenges in the ability to manage dissipated heat restrict the development of new functionalities and the durability of semiconductor devices [The International Technology Roadmap for Semiconductors. http://www.itrs.net/].

Overheating is a major contributing factor to the failure of semiconductor products and more specifically to the failure of electronic parts. Typically a 10° C. increase in operating temperature shortens useful product life by a factor of two. By causing mechanical strains, thermal cycling also impairs the durability of the devices. The power parts such as computer dies and chipsets are packaged to enable effective cooling and their workload is managed to minimize maximum thermal load and thermal load variation, the two factors with the largest impact on performance and durability of a powered device.

Typical solutions to the thermal problem are in the design and material properties of the thermal stack. Thermal stacks are rated by thermal impedance, which is measured in square meters Kelvin per watt, m²K/W. Thermal impedance is a measure of the ratio of the temperature difference between two surfaces to the steady state heat flow through them. Thermal impedance is a sum of the thermal resistance of the TIM between these two surfaces and interfacial thermal resistance on the two surfaces' contacts with the TIM. Thermal resistance increases with the thickness of the material and decreases with its bulk thermal conductivity. A stack's interfacial thermal resistance varies with the flatness and roughness of the mating surfaces and depends on the ability of the TIM to conform to the variations in the contact surface roughness and eliminate remaining smaller insulating gaps.

TIMs are used anywhere an air gap prevents heat flow between mating parts. Thermal conductivity, unit of W/m·K, (Watts per meter and Kelvin) is the parameter used to compare thermal interface materials independent of application. The performance of a TIM, however, is application dependent because of differences in surface roughness of the adjoining materials of the mating parts, and because of difference in the span of gaps to be bridged. Consequently, the heat transfer coefficient, that can be thought about as the ratio of thermal conductivity to the gap length, unit W/m²·K, is also used to qualify TIMs. The ultimate performance in heat transfer materials is given by single crystalline diamond, carbon nanotube, or graphene (maximum value is 6000 W/m·K) then silver, copper, and aluminum composites with graphitic carbon (about 400 W/m·K). Indium based solders offer up to 80 W/m·K. These costly materials play role in research and specialty applications. Indium alloys are used in applications with 20 years and longer expected product life. Graphite has unique directional thermal properties, including a conductivity up to 3000 W/m·K in the bonding plane of carbons and 16 W/m·K in the direction perpendicular to it. “Cut-and-glue” attempts to reorient graphite to traverse the heat transport gap resulted in mechanically fragile products. Typical non-metallic TIM commercial products are soft, electrically non-conductive, offer thermal conductivity in range of 1 to 10 W/m·K, and a heat transfer coefficient through 100 micron layer up to order of 100,000 W/m²·K. The thermal conductivity of commercial thermal interface materials is either nearly constant, or declines with temperature.

The flatness and roughness of the mating surfaces in a thermal stack are subject to manufacturing specifications. Less than 2 μm average is typically encountered surface roughness of the mating components of a stack such as heat sinks or spreaders. Typically the flatness of the surface of the cooling component must be less than 10 μm, and parallelism must be better than 50 μm. There is a tendency to minimize the thickness of the TIM by employing smaller tolerances on the surface finish (parallelism, flatness and roughness) of the components of the thermal stack. For contact surfaces of roughness about 0.120 μm to 0.144 μm, the corresponding roughness standard deviation is 0.0025 μm, about 2% of the average roughness. However, there is a tradeoff between the benefit of perfecting the surface finish and its cost. Often, the surface roughness of heat sink surfaces is as small as 1.3 μm with corresponding standard deviation about 0.05 μm.

Interfacial thermal resistance depends on contact of the TIM with the mating surfaces; consequently it depends on the roughness of the mating surfaces relative to the size of the heat conducting particles in the TIM. Such mating surface properties and thickness requirements are taken into account in formulating TIMs for minimum interfacial thermal resistance and maximum thermal conductivity.

The working temperature range of a device is a part-specific relevant attribute; factors such as the thermal stack size, shape, orientation, material composition, and surface finishes are subject to the design of the thermal management system. For power electronics and machinery the gaps (e.g., the gaps between the device and the thermal management hardware) are on the order of 100 microns, smaller electronic devices have distances between the stack's components in range from 5 μm to 80 μm, but more commonly now only to 20 μm, with 5 microns as a minimum for board-level device reliability.

Bulk thermal conductivity is the parameter allowing primary comparisons among thermal interface materials. Equally important for the device durability is the coefficient of thermal expansion, CTE. Due to low CTEs of semiconductors and their substrates, TIMs for semiconductor devices need to have low CTEs as well, preferably below 10 ppm/° C. to be close to the CTE of silicon 2.6 ppm/° C. CTEs of polymers is in range of 50-200 ppm/° C. while common values for metals and alloys are in the range of 10-30 ppm/° C. (with the exception for certain binary iron-nickel alloys and several ternary alloys of iron combined with nickel-chromium, nickel-cobalt, or cobalt-chromium alloys with lower, better matching CTEs).

Available TIMs come in a wide range of ambient thermal conductivities. Typical thermal interface materials whose thermal conductivity is in the order of 1 (one) W/m·K are composites incorporating particles of high thermal conductivity in a matrix enabling conformability. Typical choices for high thermal conductivity include Phase Change Materials (PCMs), Thermal Films, and Thermal Greases, whose thermal conductivity is on the order of 10 W/m·K, about one or two orders of magnitude lesser values than aluminum, the commonly used material for heat spreaders or sinks.

Typically, metal-based highly heat conductive materials that are used for mounting heat sinks and spreaders, for example silver, copper aluminum, indium and its alloys, and many solders, have thermal conductivities that decline with temperature.

Highly thermally conductive electrical insulators include boron nitride (experimentally achieved TC about 740 W/m·K, constant above ambient), [http://www.ioffe.rssi.ru/SVA/NSM/Semicond/BN/thermal.html#Thermalconductivity], aluminum nitride (declining TC) beryllia (declining TC), silicon nitride (270 W/m·K, declining TC, http://www.azom.com/article.aspx?ArticleID=3173). These materials possess high volume resistivity, and high dielectric strength and also attractive thermal expansion coefficients. These materials can be attacked by acids and alkalis and can be susceptible to hydrolysis.

Carbons have interesting intrinsic properties when considering them as TIMs. Carbons have the advantage of corrosion resistance and high thermal conductivity in the form of a single crystalline diamond, graphite, graphene, and nanotubes. However, diamond is prohibitively difficult to process, and costly. Graphite films occupy a special class. Pure graphite films (graphite foils) are low cost and have been used for a long time as thermal interface materials. Graphite films are effective over a very high temperature range (from −240° C. up to 450° C. in an oxidizing atmosphere). They offer low thermal contact resistance, however, the graphite structure's thermal conductivity in the X-Y direction (in-plane direction) and Z direction (across the gap direction) is very different. Graphite foils are rated up to 16.0 W/m·K on the z axis (across the carbon sheet in graphite) and up to 1800 W/m·K on the x-y plane (the x-y plane is oriented parallel to the plane of the carbon sheet in graphite). Pyrolytic graphite films exhibit a decline in the thermal conductivity. Between 20° C. and 500° C. the decline is about 25% in plane and about 44% out of plane of the carbon sheet. The electrical conductivity both in plane and out of plane declines by 60% to 63% in the temperature range from 20° C. to 1650° C. [data from http://www.minteq.com/our-products/minteq-pyrogenics-group/pyroid-pyrolytic-graphite/].

Graphitized carbon foams have isotropic thermal conductivity, up to 150 W/m·K, they are mechanically fragile and have CTEs that are typical for graphite.

Carbon and graphite material made by consolidation of oriented carbon fibers without a binder followed by carbonization and optional graphitization exhibits thermal conductivity in range from 390 to 750 W/m·K in the direction of the orientation of the fibers.

The main drawback of a high temperature synthetic route to carbon matrix composites, using a chemical vapor deposition (CVD) physical vapor deposition (PVD) method or high temperature consolidation, is the process temperature that the part is exposed to and the costly fabrication. This has been noted, for instance, in the case of a system, such as a pitch or resin-matrix composite with carbon fibers or nanotubes that requires cycles of pitch filling, heat treatment and carbonization in an inert atmosphere and a temperature of 1000-1500° C.

Carbon-carbon composites (graphitized pitch—carbon fiber or carbon nanotubes) have high thermal conductivity, but at 0.26 ppm/° C. the CTE of carbon-carbon composites is too low to avoid thermal stresses on contact with common components of a thermal stack. Carbon nanotubes have extremely high thermal conductivity along the longitudinal axis, but it is predicted to decline with temperature for isolated carbon nanotubes (Savas Berber, Young-Kyun Kwon, and David Tomanek; “Unusually High Thermal Conductivity of Carbon Nanotubes” Physical Review Letters 84 (20) 4613(4), 2000). The measured temperature dependence of the thermal conductivity of nanotubes exhibits a peak at about 47° C. (320K) and declines with a further increase of temperature [Phys. Rev. Lett. 87(21), 215502, 2001. Epub. 2001 Oct. 31. “Thermal transport measurements of individual multiwalled nanotubes.” Kim P, Shi L, Majumdar A, McEuen P L.]

### SUMMARY OF THE INVENTION

In some embodiments, aspects of the invention relate to nanoparticulate compositions that have useful heat transfer properties. Nanoparticulate compositions described herein can be used as thermal interface materials, for example in the context of semiconductors or other computer components or power conversion machinery such as DC/AC converters, inverters, radiofrequency generators and the like.

In some embodiments, nanoparticulate compositions comprise a mixture of carbon nanotubes (e.g., multiwall or single wall at different length to width ratios described herein, including, for example, peapods, fused nanotubes, for example “Y-shaped”, or “bamboo-like” nanotubes, or any combination of two or more thereof) referred to herein as CNTs, and nanographite particles, referred to herein as nGPs. Nanographite particles include graphite or graphene nanoparticles (e.g., nanoplatelets, nanoribbons, nanodiscs, nanocylinders, or any combination of two or more thereof), for example nanographite. In some embodiments, a carbon composite is produced from a mixture consisting of dispersed carbon nanotube and graphite particles.

In some embodiments, compositions described herein have high heat transfer properties (e.g., above 20 W/m·K thermal conductivity at 298 K or above 50 W/m·K at 368 K). In some embodiments, compositions described herein are characterized by having temperature-dependent heat transfer properties (e.g., with a heat transfer ability that increases with temperature). Accordingly, compositions described herein are useful for the dynamic temperature management of power generating, power consuming, or heat exchanging objects or devices.

In some embodiments, compositions described herein include a mixture of carbon nanotubes (CNTs) and graphite or graphene nanoplatelets (GNPs). According to aspects of the invention, one or more of the considerations described herein help promote the thermal conductivities of the compositions and/or result in thermal conductivities that are temperature dependent (e.g., that increase with temperature).

In some embodiments, the diameter (e.g., outer diameter) of the CNTs is 5-25 nm. In some embodiments, the diameter is 8-15 nm. In some embodiments the diameter is 10±1 nm. In some embodiments the OD is from 15 to 30 nm. In some embodiments, the OD is from 30 to 70 nm. However, it should be appreciated that embodiments with wider CNTs have lower based thermal conductivities that embodiments containing with narrower CNTs. In some embodiments, greater than 75%, greater than 80%, greater than 85%, greater than 90%, or greater than 95% of the CNTs have an OD within the specified range.

In some embodiments, the length of CNTs ranges from 0.5-2 micrometers. In some embodiments, the length is from 3 to 5 micrometers. In some embodiments, the length is 10 to 20 microns, 30 to 50 microns, or longer than 50 microns. In some embodiments, greater than 75%, greater than 80%, greater than 85%, greater than 90%, or greater than 95% of the CNTs have a length within the specified range.

In some embodiments, the shape of the nanoparticles (e.g., nanoplatelets) has an aspect ratio of average thickness to average lateral diameter equal to 1 to 10. In some embodiments, the shape of the nanoparticles has an aspect ratio of average thickness to average lateral diameter equal to 1 to 30. In some embodiments, the shape of the nanoparticles has an aspect ratio of average thickness to average lateral diameter equal to 1 to more than 30. In some embodiments, the average lateral dimensions of the nanoparticles are about 0.3 microns. In some embodiments, greater than 75%, greater than 80%, greater than 85%, greater than 90%, or greater than 95% of the nanoparticles have dimensions within the specified range.

In some embodiments, the average thickness of the nanoparticles (e.g., nanoplatelets) is about 30 nm. In some embodiments, the average thickness of the nanoparticles is more than 30 nm. In some embodiments, the average thickness of the nanoparticles is less than 30 nm. In some embodiments, the average thickness of the nanoparticles is less than 20 nm. In some embodiments, the average thickness of the nanoparticles is less than 10 nm.

In some embodiments, the length of the nanotubes is less than 30 times, for example less than 20 times, the lateral dimensions of the nanoparticles. In some embodiments, the length of the nanotubes relative to the lateral dimensions of the nanoparticles is between around 5:1 and around 15:1, for example around 10:1.

In some embodiments, CNTs are around 0.5 to 2 microns, 2 to 10 microns, 3 to 5 microns, or 2 to 10 microns, or 10 to 20 microns, or 20 to 30 microns, or longer than 30 microns in length, and the lateral dimensions of the nanoplatelets are submicron in scale. In some embodiments, different lengths of NTs can work for the same thickness of nGP. In some embodiments, the lateral dimensions of the nanoplatelets are no smaller than 20 nm, and the lengths of the nanotubes are no less than 100 nm.

It should be appreciated that a preparation of nanotubes or nanoparticles of a specified size range may include greater than 75%, greater than 80%, greater than 85%, greater than 90%, or greater than 95% of the nanotubes or nanoparticles having a size within the specified range.

In some embodiments, a nanoparticulate mixture is homogeneous to reduce the alignment of either the CNTs or the nGPs (e.g., GNPs). In some embodiments, homogeneity is obtained by thoroughly dispersing the CNTs among the nGPs. In some embodiments, dispersion is important for obtaining one or more thermal properties described herein.

However, it should be appreciated that a homogeneous preparation can include aligned components. In some embodiments, aligned components are detrimental to the desired thermal properties as described herein. In the absence of alignment, all orientations are equally probable, that is there is no preferred macroscopic direction of alignment of particles, detectable, for instance in their spectra measured with polarized light. If the intensity of a characteristic absorption or emission peak in a spectrum of the material is within 90+% for p and s polarized light such material is considered as lacking alignment. In some embodiments, an increase in alignment of the CNTs or nGPs (e.g., GNPs) results in a decreased thermal-dependence of the thermal conductivity.

In some embodiments, compositions of the invention are isotropic and have uniform heat transfer in all directions. This is a desirable feature, because it overcomes weaknesses of materials based on CNTs or nGPs (e.g., GNPs) alone.

In some embodiments, a composition includes CNTs and nGPs (e.g., GNPs) that are mixed with a binder. Accordingly, a binder is a third component of a composition described herein in some embodiments. In some embodiments, the mixture is prepared by combining CNTs, nGPs (e.g., GNPs), and binder materials in one or more solvents, and then curing the mixture. In some embodiments, binders and/or solvents that are used are those that generate material with a negative coefficient of electrical resistance (e.g., after curing). In some non-limiting embodiments, binder material can consist of or include one or more of the following: polymeric hydrocarbons (polyethylene, polypropylene and the like) and unsaturated polymeric hydrocarbons (e.g., polystyrene), and aliphatic (nylons) and aromatic polyamides, and polyaniline. In some embodiments, certain chemical groups in polymers should be avoided, for example chlorine substitutions and/or NxOy groups should be avoided in some embodiments.

In some embodiments, a composition (e.g., a composition comprising CNTs, nGPs (e.g., GNPs), and a binder) is mixed with a matrix. A matrix can be used to make thermal grease or phase change material or thermal adhesive or some other thermal interface product using the D-TIM as thermally conductive filler. Accordingly, a matrix can be a fourth component in some embodiments. In some embodiments, a glassy carbon is used as a matrix.

In some embodiments, the electrical properties of the solvent are less important since the solvent can be removed (e.g., by evaporation) after synthesis. In some embodiments, the weight ratio of nGP:CNT (e.g., GNP:CNT) ranges from 10:1 to 1:10, for example from 5:1 to 1:5, or from 3:1 to 1:3. In some embodiments, the weight ratio of nGP:CNT (e.g., GNP:CNT) is greater than 1, for example about 1.5:1; about 2:1; or about 3:1. In some embodiments, CNTs lose perceptible impact at a ratio of 10 to 1 of MWCNT to nGP. Also when the ratio is 1 to 10 of MWCNT to nGP, the slope of thermal conductivity decreases. However, it should be appreciated that other ratios may be used as aspects of the invention are not limited in this respect.

In some embodiments, the nGP lateral dimension is less than 1 micron, for example less than 0.5 micron, or about 0.3 micron, or less than 0.3 micron. In some embodiments, compositions are prepared using these nGP dimensions with appropriate relative CNT dimensions as described herein to produce a composite that has a high elemental carbon content (e.g., greater than 75%, greater than 80%, greater than 85%, greater than 90%, greater than 95%, or higher, for example after cure).

In some embodiments, the density of a nanocomposite described herein (e.g., a cured nanocomposite) that provides good thermal conductivities ranges from about 0.1 to about 1.75, for example from about 0.3 to about 1.5, or about 0.5 to 1, or about 0.9 g/cm³. However, it should be appreciated that other densities may be used, as aspects of the invention are not limited in this respect.

In some embodiments, methods of manufacturing that produce a homogeneous mixture of CNTs and nGPs (e.g., GNPs) are used. In some embodiments, dispersed CNTs and dispersed nGPs (e.g., GNPs) are combined. In some embodiments, dispersed CNTs are added to dispersed nGPs (e.g., GNPs). It should be appreciated that any suitable solvent may be used to disperse the CNTs and the nGPs (e.g., GNPs). This is fine

In some embodiments, a homogeneous mixture of CNTs and nGPs (e.g., GNPs) is cured. Curing can help maintain the properties of the mixture to obtain stable performance (e.g., for heat conduction, electrical conduction, and/or mechanical properties of a solid D-TIM, either self-standing or supported). In some embodiments, the curing can help evaporate the solvent from the matrix/binder, thereby increasing the density of the TIM and improving the CNT and/or nGP interaction in the TIM. In some embodiments, curing can reduce the tendency of the components to align during use (for example upon exposure to electrical current).

In some embodiments, curing can involve one or more steps that can be performed either during the manufacturing and/or after application of the nanocomposite to one or more device components. In some embodiments, curing includes a step (e.g., a drying step) to remove liquid from the manufacturing process. In some embodiments, curing includes a heating step. In some embodiments, the heating can be between 80 and 400° C., or between 100 and 250° C., for example, for 3 minutes to 72 hours, or for 30 minutes to 24 hours. In some embodiments, for CNT and nGP mixtures without additives the maximum temperature is 400° C. However, for CNT and nGP mixtures with additives the cure temperature is limited to the temperature limit at which the additives become unstable. For organic materials this temperature typically increases above the decomposition of the additive in absence of the CNT or nGP. The maximum cure temperature is thus an intrinsic property of the specific composition. In some embodiments, the duration of the cure is determined by the achievement of one or more stable properties of interest, as opposed to by time. For example, electrical conductivity that is stable for an hour in the absence of perceptible Joule heating can be sufficient. The necessary cure might be less demanding. In some embodiments, it should be appreciated that curing should be performed under conditions that avoid excessive loss of the binder material (typically the binder is less thermally stable than the carbon components). In some embodiments, curing is performed under conditions that avoid excessive loss of elemental carbon (e.g., that could occur at temperatures above 400° C., or in presence of oxidation catalysts, such as metal particles, for example Ag).

In some embodiments, curing can be performed before an application of the D-TIM composition-based material as a heat transfer medium. The product of the cure can be a self-standing material or a supported material. Supports can be in solid form (e.g., plates, films, and porous materials such as woven, knits, mats or sponges). In some embodiments, the solid support material can be a ceramic, glass, graphite, glassy carbon, a metal, or a polymer or a semiconductor.

In some embodiments, a thermal interface material and/or a filler can be added to modify certain auxiliary properties such as electrical conductivity, CTE, and/or viscosity. For example certain polymeric particles can be added. However, in some embodiments, a composition described herein can be added to an existing thermal interface materials to modify the properties of the thermal interface material.

In some embodiments, a composition is metal-free, for example Ag-free (or only contains trace amounts of Ag). In some embodiments, the presence of Ag or other metal in a nanoparticulate mixture described herein reduces or eliminates the temperature-dependence of thermal conductivity. In some embodiments, compositions do not contain (or only contain trace amounts of) one or more or all transition metals or noble metals. In some embodiments, compositions do not contain (or only contain trace amounts of) one or more of the following metals, nickel, cobalt, copper, molybdenum, vanadium, manganese, platinum, iridium, osmium, etc., or any combination thereof. In some embodiments, one or more metal catalysts that are used in the synthesis of nanocarbons reduce or eliminate the temperature-dependence of thermal conductivity for a composition described herein. Accordingly, in some embodiments, a composition does not contain (or only contains trace amounts of) metal catalysts that are used in the synthesis of nanocarbons. Typically the concentration of the metals used as catalysts in synthesis of a CNT is below 0.1%. Standard techniques for removing metals from CNT and from graphite particles are well known. In some embodiments, they are used before preparing the D-TIM. In some embodiments, the metal content can be confirmed or specified upon purchase of the substrates.

In some embodiments, metal particles with an average size above 10% of the average lateral diameter of the nGP are excluded. For example, metal nanoparticles larger than about 30 nm should be eliminated from the bulk of a preparation involving nGP with an average lateral diameter of about 0.3 microns.

In some embodiments, the presence of defects in the nanocomposite material increases the slope of the temperature-dependence of thermal conductivity (with a steeper slope in the presence of more defects). Accordingly, in some embodiments a first composition has a lower thermal conductivity at lower temperatures and a higher conductivity at higher temperatures than a second composition with fewer defects due to the different slopes of thermal conductivity. In some embodiments, the presence of defects can be identified or quantified by determining the relative intensity of the D Raman band to the G Raman band of the CNT and nGP. Typically the D band maximum intensity is less than 25% of the intensity of the G Raman band of the material.

In some embodiments, a defect is produced by implanting hydrogen, silicon, oxygen, argon, or other rare gases in nanotube or nanoplatelet compositions. In some embodiments, functional defects can be obtained by physical association with polarizable materials such as materials containing groups including oxygen, nitrogen, phosphorus, sulfur and/or other materials known to be electrophilic, for example when such materials are implanted into a carbon lattice. In some embodiments, Argon atoms may produce sufficient disruption to provide a functional defect. In some embodiments, one or more of the following atoms can be used to produce a sufficient disruption: N+, N2, O+, O2, P, H+, B+, B2, Si, C, F−, CN, and/or CL. In some embodiments, the intensity of D and G Raman spectra of CNT and nGP can be analyzed to determine the appropriate level of damage from the implant.

It should be appreciated that implantation can occur at any appropriate stage during the preparation of a nanocomposite. For example, implantation can occur post CNT growth and before mixing the CNT with the binder/matrix. Implantation can also occur during cure or post cure in some embodiments.

In some embodiments, defects can be increased by stretching the material in one or more directions after curing (whereas stretching before curing can result in the alignment of one or more components of the material and reduce the temperature dependence of thermal conductivity). In some embodiments, the act of mechanical mixing the materials, for example the action of combining the binder/matrix with the CNT/nGP can create defects in the final composite material.

In some embodiments, one or more substitutions in the carbon lattice is expected to induce or enhance thermal dependence, for example in materials that do not exhibit temperature dependent thermal conductivity, by introducing defects into the composition.

In some embodiments, individual crystalline carbon components of the compositions described herein can, as isolated single-molecular particles, exhibit ultimate values in a number of useful physical properties, including heat transfer ability. According to some aspects of the invention, without wishing to be limited by theory, the introduction of one or more defects and/or a loss of continuity in the material interrupts the heat transfer path and brings resistance to heat transport. Re-aggregation of the individual components of the material, however, as random aggregates of crystalline-ordered particles, the same carbon species display many orders of magnitude deterioration of the heat transfer ability. Homogeneity is important for the desired thermal properties. Accordingly, if by accident the CNT reaggregates with CNT and nGP reaggregates with nGP instead of intermixing, such result will be detrimental to the thermal performance of the resultant material. In other words, separation of CNT from nGP by self-aggregation fails to produce the desired D-TIM properties.

It is of note that carbon nanomaterials have been identified as potential candidates to replace silicon in high-speed devices. However, aspects of the invention relate to carbon nanoparticulate material that has novel heat transfer properties.

Certain embodiments of the invention are directed toward thermal interface materials for use in heat transfer management, referred to herein as D-TIMs (Dynamic Thermal Interface Materials). In some embodiments, D-TIMs described herein rely on the thermal characteristics of a composition comprising or consisting of a mixture of carbon nanotubes (CNTs) and graphite nanoplatelets or graphene nanoplatelets, (nGs). In some embodiments, CNTs and nGs are provided in appropriate shapes, sizes, degree of interpenetration, mixing proportions, and/or with a small amount of specifically selected polymer binder, all together referred to herein as a nanocarbon composite or as a D-TIM.

In some embodiments, aspects of the invention relate to methods of providing heat conductivity by combining carbon nanotubes and graphite particles in a specifically organized composite. This new composite can function as a thermal interface material. In some embodiments, the thermal conductivity of a D-TIM at ambient temperature is an order of magnitude larger than that of the typical thermal interface materials in commerce. For example, in some embodiments the thermal conductivity of a D-TIM at 25° C. exceeds by no less than an order of magnitude the thermal conductivity of random pellets of either graphite or carbon nanotubes alone. Also, in some embodiments the thermal conductivity of a D-TIM composite grows monotonically and reversibly with temperature. In contrast, the individual components of a D-TIM do not exhibit this feature. The thermal conductivity of graphitic materials is either constant or decreases with increasing temperature. Accordingly, the positive dynamics of thermal conductivity is an emergent feature of the composite.

In some embodiments, CNTs can be in form of isolated CNTs or bundles of nanotubes dispersed among nG platelets forming a CNT-nG aggregate. For certain applications, the sizes of the particles are limited by geometrical features of a device requiring thermal management, typically in range from 5 to 100 μm. The largest of these is the geometrical distance between the device's components that the D-TIM is meant to fill and bridge, consequently setting the scale of the high limit on any dimension of any of the particles in the D-TIM in relation to the D-TIM use. More specific conditions arise from the requirement to achieve high thermal transport through the distance the TIM is bridging. These specific material requirements are described in more detail herein. Non-limiting examples are presented that relate to typical industrial practices where such distances are larger than 5 micrometers.

In some embodiments, the lateral dimensions of the nG particles are in the plane of a carbon sheet of graphene. In some embodiments, numerous graphene layers are stacked, but the area of the carbon lattice plane, that is the lateral dimension of the particle is small, it can be smaller than the thickness of the stack of graphenes in the graphite crystalgraphene, and the thickness of the nG is perpendicular to its lateral dimension. In some embodiments, the aggregates can be connected by the CNTs that can penetrate more than one aggregate. The CNT-nG aggregates can form spontaneously during mixing of CNTs and nG. Effective mixing is important to generate a homogeneous mixture (with the CNTs and nGPs sufficiently dispersed). Effective methods of mixing are known, for instance with ultrasound exposure or grinding of the suspension of the particles in a solvent which is subsequently removed. In some embodiments, the suspension has the CNT and nG nanoparticles conforming to specific size and proportion requirements as described herein.

It should be appreciated that the CNTs can be single-walled carbon nanotubes (SWNTs), double-walled carbon nanotubes (DWNTs), multi-walled carbon nanotubes (MWNTs), or any combination thereof, as aspects of the invention are not limited in this respect. In some embodiments, the average outer diameter OD of the CNT ranges from 1 to 15 nm and the average length ranges from 0.5 to 20 micrometers, while the nG particles have a lateral diameter centered at 0.3 micron. In certain embodiments, a 0.3 micron nanographite can be replaced by functional equivalents such as graphene nanoplatelets or nanoribbons.

In some embodiments, a composite composition includes a polymeric binder. The polymeric binder can contact the entire CNT-nG aggregate or only a part thereof. Non-limiting examples of a polymer coating can include or consist of one or more of a polyolefin, e.g., polyethylene or polypropylene, cellulose or cellulose derivatives, polyalcohol, polyamide, polyurea, polyurethane, polysulfonamide, polyester, polycarbonate, polyindole, polyporphyrine, polyester, rubber, silicone, polythiophene, polypyrrole, polyamines (e.g., polyaniline) or any other polymer delivered by a solvent or polymerized in situ or uniformly incorporated by any other method.

In some embodiments, the polymer can be cross-linked. However, it should be appreciated that the polymer does not necessarily form a continuous matrix. In some embodiments, the polymer is a minor component of the mixture. Certain polymers and processing solvents (e.g., halogenated, or certain ketones such as technical grade acetone) are less desirable because of their ability to convert CNT-nGP composites described herein from negative temperature coefficient (NTC) type compositions to positive temperature coefficient (PTC) type compositions. This can be detrimental to one or more of the thermal properties, because the high thermal conductivities and temperature-dependent thermal coductivities described herein are associated with NTC type compositions.

Accordingly, in some embodiments aspects of the invention relate to a composite material comprising a dynamic thermal interface material (D-TIM) with carbon nanotubes (“CNTs”) and nanographite particles (nGPs), for example graphite nanoplatelets in concentrations that introduce a reversible increase in the thermal conductivity with temperature. The D-TIMs can be used in thermal stacks employed in thermal management of devices and processes. In some embodiments, the D-TIM material of claim comprises a crystalline carbon nanoparticle composite consisting of (1) carbon nanotubes dispersed among (2) a plurality of types of crystalline nano-carbon particles that contain platelets of graphite or graphene. In some embodiments, the spaces among the crystalline carbon nanoparticles may contain a (3) compatible binder molecule or molecules, and the final composite demonstrates positive thermal dependence of thermal conductivity. In some embodiments, at least a two-fold increase of thermal conductivity is obtained in the temperature range from 20° C. to 75° C., with a continuation of this trend for increasing temperature.

In some embodiments, the D-TIM's crystalline carbon nanoparticles' composition comprise no less than 60% of TIM's mass, and the crystalline carbon nanoparticles consist of CNTs in range from 20% to 80% by weight; and carbon in the form of graphite or graphene nano-platelets can also span the range from 20% to 80% by weight. In some embodiments, CNTs range from 30% to 55% by weight, and graphene or graphite is up to 70%.

In compounding with component (2) above, the beneficial effect of increasing thermal conductivity with temperature in a D-TIM heating can be obtained using carbon nanotubes such as single wall carbon nanotubes, double wall carbon nanotubes and multiple wall carbon nanotubes or any mixture thereof such that the component (1) particles have the length longer than ten-fold their outer diameter but no longer than 5 μm to 80 μm.

In compounding with component (1) above, the beneficial effect of increasing thermal conductivity in a D-TIM heating can be obtained using carbon nano-platelets such as graphene or unzipped carbon nanotubes or unzipped graphitized carbon nanotubes or graphite or any mixture thereof such that component (2) particles have an in-plane diameter larger than their average thickness and shorter or equal to 5 μm to 80 μm.

In compounding with components (1) and (2), the beneficial effect of increasing thermal conductivity in a D-TIM heating can be obtained with or without using polymer binders such as cellulose-based polymers, acrylates, poly-olefins, polyesters, polycarbonates, rubbers, some thermoplastics, or thermosets, and/or elastomers provided the thermal coefficient of electrical resistance remains negative.

In some embodiments, the outer diameter of component (1), the CNT, is contained in a range from 8 to 15 nm. In some embodiments, the CNTs are multiple-wall carbon nanotubes.

In some embodiments, component (2) of the D-TIM, the graphite or graphene carbon particles, have a thickness no larger than 10% of their average in-plane dimension of the carbon sheet.

In some embodiments, the average lateral diameter of component (2) of the D-TIM is no larger than 20% of the length of component (1) in the composite.

In some embodiments, graphite platelets of the D-TIM are either graphite or graphene in various shapes with over 50% crystallinity. In some embodiments, graphite or graphene nano-platelets and CNTs of the D-TIM comprise 90-95% by weight of the mixture with the remaining portion consisting of the binder or binders, additives, and other polymer molecules along with organic and/or inorganic solvents and the like, although other ratios of the graphite or graphene nano-platelets and CNT ranging from 2% to 99.9% can be used.

In some embodiments, component (1) is nano-dispersed in component (2) and the sum of components (1) and (2) is nano-dispersed in the optional component (3) of the D-TIM. In some embodiments, the optional component (3) of D-TIM can be a polyolefin, e.g. polyethylene or polypropylene, polyether, polyester, polyamide, polynitrile, rubber, cellulosic compound, polyalcohol, any glycol, polyurea, polyurethane, polysulfonamide, polycarbonate, polyaniline, polyindole, polyporphyrine, polythiophene, polypyrrole, polyaniline or any other polymer that can be used to produce an NTC type semiconductor, delivered or polymerized in situ by any method (e.g., any polymer using any method that will produce a composite that is an NTC type semiconductor).

In some embodiments, a thermal stack and/or other supporting D-TIM surfaces can be used, but these surfaces are not limited to flat interfaces. Other surfaces with texture, curvature and surface area increasing topography can be used.

In some embodiments, material interfaces can include, but are not limited to, metals such as silver (Ag), copper (Cu), gold (Au), aluminum (Al), tungsten (W), indium (In), tin (Sn), gallium (Ga), zinc (Zn), beryllium (Be), silicon (Si), nickel (Ni), chromium (Cr), molybdenum (Mo), vanadium (V), titanium (Ti), cadmium (Cd), selenium (Se), antimony (Sb), arsenic (As), bismuth (Bi), lead (Pb), cobalt (Co), zirconium (Zr), and their alloys, carbides, tungstates, phosphides, silicides; ceramics (e.g., AlSiC, Aluminum nitride, Boron Nitride, Silicon Nitride and their respective Carbides, Oxides), Metal-Carbon composites, Fe, all grades and alloys of steel, various solders, thermally conductive polymers, clays, diamond, glass, polyethylene, a variety of plastics, or any combination thereof.

Other advantages and novel features of the present invention will become apparent from the following detailed description of various non-limiting embodiments of the invention when considered in conjunction with the accompanying figures.

### BRIEF DESCRIPTION OF THE DRAWINGS

FIG. 1 shows non-limiting embodiments of a thermal stack—FIG. 1A illustrates the relative arrangement of thermal interface material, a power package, a heat spreader, and a heat sink, FIG. 1B illustrates heat flow (arrow) through a model of a thermal stack with the dark grey layer representing a TIM, and the walls of the thermal stack are light grey, FIG. 1C illustrates surface roughness at the interfaces of the TIM and the walls of the thermal stack;

FIG. 2 shows a non-limiting scanning electron micrograph of a 600 nm by 600 nm box of a nanocomposite illustrating a lack of alignment among carbon particles, and the existence of associations of MWCNTs and nGPs;

FIG. 3 shows an example of thermal conductivity as a function of temperature for non-limiting nanocomposites, FIGS. 3A and 3B illustrate the temperature dependence of thermal conductivity of D-TIMs consisting of 65% nGP with 0.3 micron lateral diameter, 32% MWCNT with 8 to 15 nm OD, and about 10 micron long, and 3% acrylate polymer binder by weight, the D-TIMs illustrated in FIG. 3B were more homogeneously mixed than the D-TIM illustrated in FIG. 3A;

FIG. 4 shows relative thermal conductivities as a function of temperature for several nanocomposite batches;

FIG. 5 illustrates a non-limiting example of the temperature dependence of thermal conductivity of a D-TIM consisting of 97% total nano carbon particles and 3% acrylate polymer binder by weight—the nanocarbon nanoparticles are nGP with 0.3 micron lateral diameter, 20 nm average thickness and MWCNT with 10±1 nm OD and length from 3 to 5 micron; nGP and MWCNT are in 2 to 1 ratio by weight—FIG. 5A shows the absolute thermal conductivity and FIG. 5B shows the relative thermal conductivity;

FIG. 6 illustrates non-limiting example of showing that the relative thermal conductivity in the presence of silver particles in the sample is practically constant in comparison with the sample without added metallic silver (see FIG. 5); and,

FIG. 7 shows a non-limiting example of the effect of alignment of CNTs and/or nGPs on the temperature-dependent thermal conductivity of a D-TIM.

### DETAILED DESCRIPTION

According to aspects of the invention, hybrid nanomaterials composed of carbon nanotubes (CNTs) and graphene or graphite can have outstanding properties that are superior to any of the components used alone. In some embodiments, hybrid nanomaterials described herein can be used as dynamic thermal interface material (D-TIM) that can have a temperature-dependent change in heat transfer coefficient ranging from 10,000 to 1,000,000 W/m2K on a path length of about 100 microns over a temperature change of 50 to 100° C.

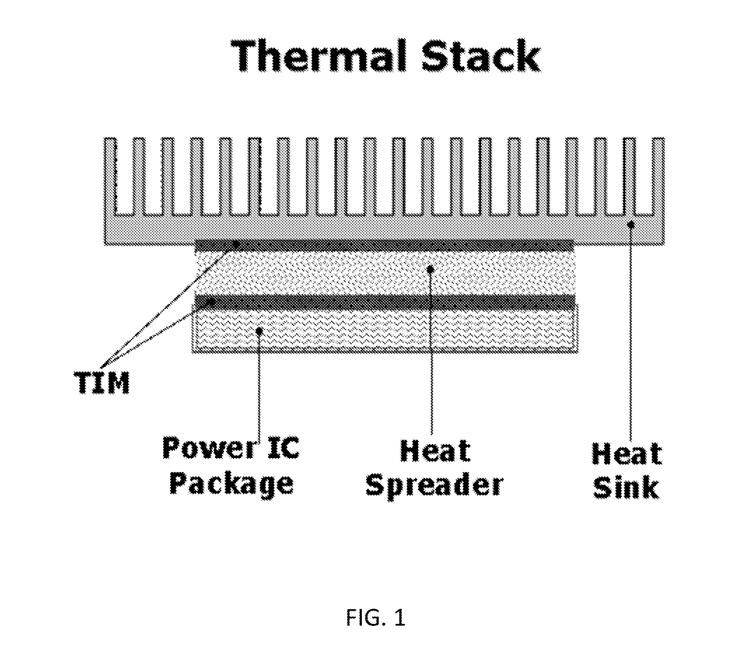

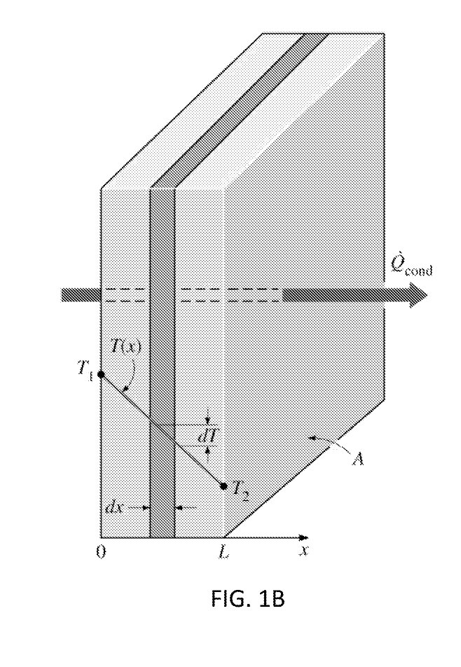

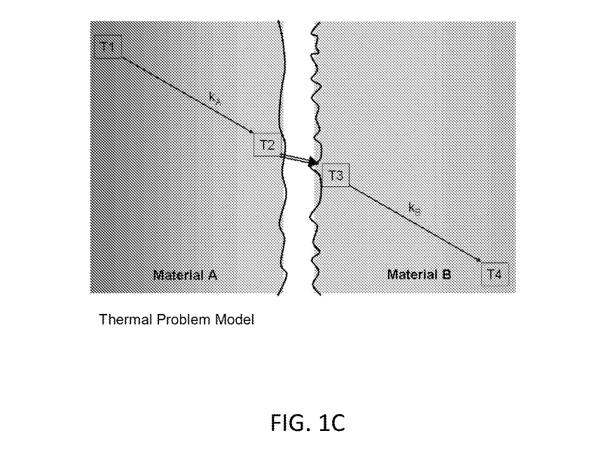

Accordingly, compositions described herein can be used as thermal interface material (TIM) in a thermal stack. A non-limiting example of a thermal stack is illustrated in FIG. 1, where a first layer of TIM is shown between a power integrated circuit (IC) package and a heat spreader and a second layer of TIM is shown between the heat spreader and a heat sink. FIG. 1B illustrates heat flow (arrow) through a model of a thermal stack with the dark grey layer representing a TIM, and the walls of the thermal stack are light grey. FIG. 1C illustrates surface roughness at the interfaces of the TIM and the walls of the thermal stack. However, it should be appreciated that a TIM of the invention can be used in any configuration to promote heat transfer between a first surface and a second surface or between a first surface and the surrounding medium (e.g., air, gas, or other medium).

In some embodiments, compositions comprise a mixture of carbon nanotube (CNT) and graphene/graphite nanoparticles (GNPs) configured to have one or more of the following properties: a) a high base thermal conductivity; b) isotropic conductivity (e.g., so that bridging of the thermal gap between electrical components occurs effectively) and/or; c) a thermal conductivity that is positively and reversibly dependent on temperature (also referred to as “dynamic thermal conductivity” herein).

It should be appreciated that graphene/graphite nanoparticles (GNPs) as used herein can be nanoplatelets, nanoribbons, or other suitable nanoparticles as described herein.

In some embodiments, the isotropy and/or dynamic thermal conductivity of a composition described herein is related to the proportions of thickness and length for both components. In some embodiments, a composition has nGP of no more than 30 nm average thickness, while the average lateral diameter is about 0.3 micron. In some embodiments, for this size of nGP, an effective outer diameter (OD) of a CNT (e.g., a MWCNT) is larger than 7 nm and less than 15 nm, while the average length is about 5 micrometers (e.g., 4.5 to 5.5 μm). However, it should be appreciated that other sizes and combinations can be used as described in more detail herein.

In some embodiments, a high base thermal conductivity is related, at least in part, to the following factors: (1) the purity and crystalline perfection of the substrate CNT, and/(2) the fabrication method.

Accordingly, in some embodiments D-TIMs can be used to provide dynamic management of heat transfer via large positive temperature dependence of the heat transfer rate. This will for instance, lower the probability of thermal failures, and also enable increases in computing power.

In some embodiments, a TIM disclosed herein is a die level thermal interface material (TIM) system whose thermal conductivity reversibly increases with temperature, and that has a base thermal conductivity that is comparable to state of the art thermal interface material.

Accordingly, in some embodiments a D-TIM described herein differs from existing state of the art thermal interface materials in that its thermal conductivity increases with temperature in addition to having a high thermal conductivity (e.g., 30 W/K·m±3.75 W/K·m after curing) at ambient base temperature (e.g., base temperature of 25° C.). In some embodiments, a D-TIM achieves a thermal conductivity comparable to metals and solders at temperatures ranging from 60° C. to 100° C., and also is corrosion resistant and lightweight.

In some embodiments, a homogeneous mixture of CNTs and nGPs (e.g., GNPs) is stabilized by curing (for example by heat treatment). Compositions described herein (including cured D-TIMs) exhibit a novel reversible increase of thermal conductivity with temperature above a value observed at ambient (25° C.) temperature. In some embodiments, a D-TIM uniquely combines high ambient thermal conductivity which reversibly increases with temperature. In some embodiments, a D-TIM has a CTE that is higher than carbon-carbon composites but lower than 10 ppm/° C. It also can be lightweight (e.g., with a density below 2.25 g/cm3) and corrosion resistant.

Size and Ratio Considerations for the CNT and nGP Components:

According to aspects of the invention, the size and relative amounts of the different components of a composition can impact its thermal properties.

In some embodiments, high ambient thermal conductivity is obtained when the crystalline carbon material contains carbon nanotubes (e.g., multiple-walled carbon nanotubes) with an outer diameter ranging from around 5 nm to around 20 nm (e.g., from around 7 nm to 16 nm). Since the outer tubes are larger than the inner tubes, they act as a protective shield for the latter under processing or in use while the inner tubes provide the structural stability for the outer ones [D. Christophilos, et al. Phys. Rev. B, 76, 113402, (2007)].

In some embodiments, the thickness of the graphitic carbon, as defined by the center of the distribution, should be less than 100 nm, for example less than 30 nm. However, other thicknesses can be used, for example thinner graphitic platelets can be desirable for some applications. In some embodiments, the graphitic platelets can be as thin as containing only a few graphene layers (e.g., have thickness as low as about 2 nm). However, in some embodiments, carbon nanotubes with OD less than 8 nm are less effective.

In some embodiments, the mass ratio of nGP:CNT (e.g., GNP:CNT) is about 2:1. However, other ratios may be used, for example from about 10:1 to about 1:1.

In some embodiments, the functional content of nGP in the total composition ranges from 70% to 30% (by weight).

In some embodiments, the average lateral diameter of the nanoplatelets is no less than 10 fold larger than their thickness. However, it should be appreciated that different shapes may be used. For example, particles with elongated planes such as nanoribbons (e.g., graphene nanoribbons) can be used in some embodiments provided the compositions are prepared to minimize any detrimental effect of alignment (elongated particles can align more easily than other particles).

In some embodiments, the ratio of the lateral diameter to the thickness ranges from about 300:1 to about 200:1, to about 100:1, to about 50:1, to about 10:1, or less than 10:1, for example 5:1 or less, although this thickness may reduce the effectiveness of the composition.

In some embodiments, the maximum lateral diameter is no more than 10 microns, and the minimum lateral diameter is no less than 20 nm. In some embodiments, the average thickness for the largest lateral diameter needs not exceed 30 nm, and the highest thickness for the smallest diameter needs not exceed 2 nm, while the lowest thickness is the thickness of a single graphene layer.

In some embodiments, the diameter (e.g., outer diameter) of the nanotubes is about 7-16 nm, for example about 8-15 nm, about 10 nm (e.g., +/−1 nm). However, it should be appreciated that different diameter sizes (e.g., outer diameter sizes) may be used. For example, 5-25 nm, but smaller or larger diameters may be used in some embodiments.

In some embodiments, the length of the nanotubes is determined relative to the lateral dimension of the platelets. For example, in some embodiments, the ratio of CNT length:nGP lateral dimension is less than 30:1, from 30:1 to 20:1, about 20:1, less than 20:1, from 20:1 to 10:1, about 10:1 or less. In some embodiments, the CNT length is about 0.5-20 microns, or about 2-10 microns (e.g., about 4.5 to 5.5 microns). In some embodiments, the CNT length is about 2-10 microns and the lateral dimensions of the nGP are submicron in size. However, it should be appreciated that different lengths and ratios of material may be used in some embodiments. In some embodiments, the length does not exceed 10 microns. In some embodiments, there is little or no advantage to the length of the CNT exceeding 20 microns, but there is no significant disadvantage beyond about a 30% drop in thermal conductivity at ambient temperature for longer CNTs.

However, in some embodiments the CNT cannot be shorter than the lateral diameter of the nGP. In some embodiments, when larger nGPs are used, then proportionally longer CNTs are used. However, the diameter and thickness of the CNT does not need to change. In some embodiments, a composition is determined by the ratio of lateral diameter of the nGP to the length of the CNT.

Accordingly, in some embodiments, the lateral diameter of nGP, LD(nGP), is smaller than the average length of the CNT. In some embodiments, the MWCNT outer diameter OD is 10 nm. In some embodiments, the MWCNT length is greater than 20×LD(nGP) and does not need to be longer than 100×LD(nGP), which for an LD(nGP) of 0.3 micron corresponds to L(MWCNT) of 30 microns. In some embodiments, this size range is reasonable for the gaps in thermal stacks in electronic packaging that tend to be small, e.g., 20 micron. Due to its flexibility, a MWCNT having a length of about 30 microns is still useful in such a narrow gap. In power electronics, the gaps tend to be larger (for example around 100 microns). In this context, the nGP average lateral diameter can be scaled up, but generally not much beyond what the average roughness of the mating parts would allow. In some embodiments, an average surface roughness can be up to around 15 microns.

In some embodiments, the aspect ratio of the average lateral dimension of the graphitic material to its thickness is larger than 10 (ten) as explained in relation to typical surface roughness encountered in the applications.

In some embodiments, the lateral diameter of the nGP that is used is limited by the asperities in the surface of the thermal stack. For example, if the stack has an average roughness of 1.3 micron, then nGP having an average lateral diameter of about 0.3 micron can be appropriate. For rougher surfaces, nGP having larger lateral diameters can be used.

In general, asperities are due to the surface finish of the mating parts in a device. Typically, their characteristics are summarized by average surface roughness, although they have hierarchical structure. Larger average roughness leads to increase in specifications for the gap width and then the thickness of the thermal interface material. TIMs filling thick gaps should have high bulk thermal conductivity. In some embodiments, 100 micron or higher is considered a thick gap. Thin gaps are 50 micron wide or narrower. For such gaps the TIM should have low thermal contact resistance in addition to good bulk thermal conductivity.

In some embodiments, thermal contact resistance can be modified by the addition of a thin (e.g., on the order of 100 nm or less) surface layer of particles (e.g., such as low structure high graphitization carbon black) to the surface of the TIM (e.g., impressed into the surface). Preliminary tests indicate that such treatment of a D-TIM surface can be effective in lowering the thermal contact resistance and have no detriment on the bulk properties of D-TIM.

Binder Considerations:

In some embodiments, the CNTs and nGPs (e.g., GNPs) are mixed with one or more binders. One or more of the components may be suspended in a solvent to promote mixing during manufacturing. In some embodiments, binders and/or solvents are selected to produce material having a negative coefficient of electrical resistance after curing.

In some embodiments, adding a binder at about 1 to 5% by weight is responsible for the reversible dependence of thermal conductivity on temperature. The activation of oscillatory motions in the binder can affect the activating energy of the heat transport. In some embodiments, the thermal properties of the binder can limit the operating temperature range of the composite.

A binder can be a polymer such as derivatized cellulose, acrylic polymer, or thermoplastic, thermoset, and other polymers may also work. The polymeric binder can contact the entire or only a part of the CNT-nG mixture. The polymer can be a polyolefine, e.g. polyethylene or polypropylene, polyamide, polyurea, polyurethane, polysulfonamide, polyester, polycarbonate, polyaniline, polyindole, polyporphyrine, polythiophene, polypyrrole, polyaniline or any other polymer delivered by a solvent or polymerized in situ by any method. The polymer can be cross-linked. It is not necessary that the polymer forms a continuous matrix. In some embodiments, the polymer is a minor component of the mixture.

In some embodiments, binder material is electrically polarizable. For example, moderately polar polymeric binders are effective. The selection of an appropriate binder can depend, in part, on its stability under conditions of use. In general, the presence of nitrile, amino or amide groups in the polymeric binder is desirable, and the presence of ether, hydroxyl groups, carboxyl, carbonyl, and ester groups is acceptable. However, chlorination is undesirable in some embodiments. In some embodiments, rotatable side-chain substitutes in the binder can be advantageous.

In some embodiments, the quality and quantity of the binder plays the role of a mediator. In some embodiments, the quantity by weight does not exceed coating of the C surfaces by more than several monolayers. This generally corresponds to about a maximum 5% by weight. Phonon-electron coupling can be made thermally activatable by introduction of the side groups that are attached by single bonds to the polymer backbone. The thermally-activated rotation of these groups can lead to interaction with the electronic structure of associated carbons thus thermal excitation of polarons and the near field radiative energy transfer among CNT and/or nGP. For these groups to be effective, their oscillation frequency and orientation as well as proximity to the carbon and their polarizing chemical field effect synchronizes to the carbons. This oscillating synchronization can be thermally activated. This idea is similar to a concept of chemical field effect transistor, but instead of a single device you have a network that enables and carries out the energy transport. In that it is well known that polyamides and various biopolymers (e.g., oligonucleotides) wrap about the CNTs, and cause changes in their electronic structure observable in the optical spectra of such complexes.

If SWCNT or DWCNT are used, debundling and pre-wrapping of the tubes with the binder can be advantageous prior to addition into nGP.

Matrix Considerations:

In some embodiments, a matrix comprises one or more carbon allotropes. In some embodiments, a matrix can include oil. However, in most embodiments oil should be a minor component.

As used herein, a matrix can refer to the most abundant component of a composition. For example, the matrix can refer to the most abundant nanocarbon being the matrix for a less abundant nanocarbon. Accordingly, for a 3-component D-TIM, the graphitic nanoparticles (e.g., nanoplatelets) are typically the matrix.

In some embodiments, D-TIM or the D-TIM substrates (e.g., the two nanocarbons and the binder) can be dispersed in a base oil. The dispersion of the D-TIM in the base oil is a paste. This paste, dependent on selection of the base oil and other fillers, can be formulated into a thermal grease or a phase change material. The fillers mediate the paste's viscosity, CTE, electrical conductivity according to known principles and procedures.

When one uses the D-TIM to make a thermal paste, by dispersing it in an oil, then the oil becomes a new matrix, or ‘oil base’ and the D-TIM becomes the thermally conductive filler. In some embodiments, paraffins, polyfluorinated oils, or other oils can be used.

Alignment Considerations:

In some embodiments, compositions described herein have more desirable properties in the absence of particle alignment. On a pair-wise interaction of nGP and CNT there can be preferential local alignment due to preferential orientation of CNT versus graphite, see Paulson paper [S. Paulson, A. Helser, M. Buongiorno Nardelli, R. M. Taylor II, M. Falvo, R. Superfine, S. Washburn, “Tunable Resistance of a Carbon Nanotube-Graphite Interface”, Science, 290(5497), 1742-1744, (2000)]. However, flat alignment of nGP is undesirable. Accordingly, in some embodiments, compositions described herein prevent or reduce the alignment of nGPs due to the numbers and sizes of the CNTs that interfere with the lateral plane alignment of nGPs. It should be appreciated that graphite/nGP alone does have a tendency to align and this leads to preferential conduction in the plane of alignment which is not desirable in some embodiments.

In some embodiments, compositions are isotropic. Isotropic compositions are characterized by an absence of direction-dependent properties such as heat conductivity. In some embodiments, if the difference of thermal conductivity in a certain arbitrarily selected direction is no more than 10% different from thermal conductivity measured on any axis perpendicular to the first, then such material is considered isotropic. It should be appreciated that anisotropy is generally undesirable. In some embodiments, a small degree of orientation of the components is acceptable (for example about 30% or less). However, higher degrees of orientation can lead to anisotropy that is undesirable. In some embodiments, anisotropy is undesirable because it can introduce local hot and cold spots.

In some embodiments, compositions described herein comprise homogeneous mixtures of CNTs and graphene or graphite nanoplatelets (gNPs) that are not aligned or that have a low degree of alignment. According to aspects of the invention, alignment of the nanoparticulate components is detrimental to their thermal conductivity properties. Rather, the presence of a mixture of nanoparticles having different relative orientations promotes increased thermal conductance (for example across the plane of sheet of TIM) and contributes, at least in part, to a temperature-dependent thermal conductivity. In contrast, current opinion holds that the inherent CNT-graphene loose junctions present in the CNT-graphene composites prepared by existing methods such as mixing “significantly hinder the realization of the full potential held by CNT-graphene hybrids.” Instead covalently bonded CNT-graphene pillared architectures are generally proposed [ACS Nano. 2010 Feb. 23; 4(2):1153-61. “Modeling of thermal transport in pillared-graphene architectures.” Varshney V., Patnaik S S, Roy A K, Froudakis G, Farmer B L. Source: Materials and Manufacturing Directorate, Wright Patterson Air Force Base, Dayton, Ohio, USA.] The issue of CTE of these composites has not been addressed. However there is no reason to expect large departure of the CTE of pillared CNT-graphene from properties of either pure component, which are too low to avoid thermal stresses with silicon based or polymeric packages or broadly in use metal heat sinks such as aluminum. The common feature of the high TC TIMs is a lack of increased thermal conductivity with temperature above ambient temperature.

In contrast, compositions described herein are characterized by reversible increase in thermal conductivity with temperature. As a result, they can be used for a variety of applications. In some embodiments, a nanomaterial described herein can be useful to shorten the warm-up time and lower the working temperature of one or more device components, thus better accommodating transfer of variable heat load arising from changes in power consumption resulting from variable workloads on a device playing the role of the powered part of a thermal stack. Variable workloads are typical in power-generating equipment, various machines, and especially in electronic computing devices. Lower working temperatures can allow faster operation of a computing device, and prolong its useful life, lower energy consumption, lower cost of support and total cost of ownership.

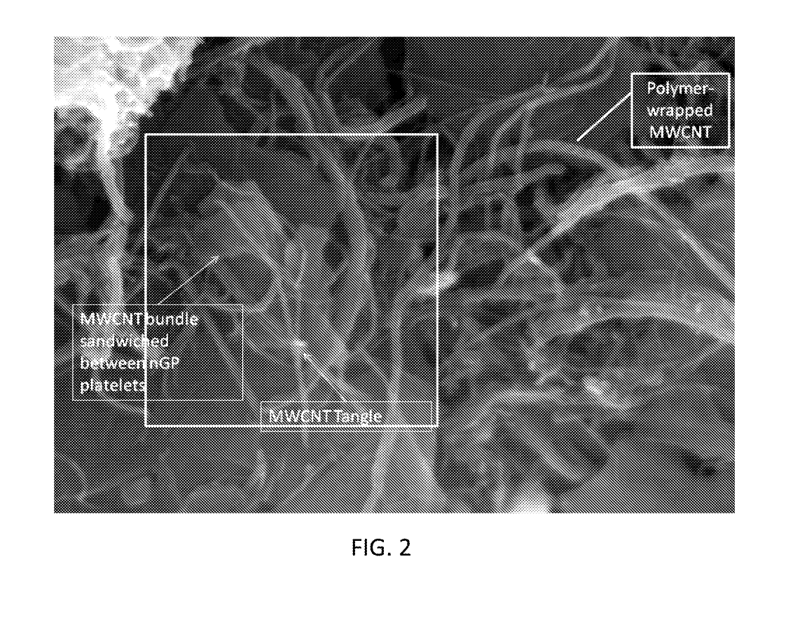

FIG. 2 shows a scanning electron micrograph of a mixture of MWCNTs and nGPs illustrating that they are not aligned, but rather are randomly distributed or dispersed within the binder material. FIG. 2 illustrates several features of a D-TIM as described herein. In some embodiments, a D-TIM is a nanoscale mixture of commonly available components: (1) carbon nanotubes (for instance about 30% by weight), (2) crystalline carbon nanoplatelets (for instance about 60% by weight) such as graphite or graphene, and optionally (3) a small amount (for instance less than 10% by weight) of a binder.

Dispersion Considerations:

It should be appreciated that any method of dispersion that leads to uniform mixing and dispersion of carbon nanotubes in carbon nanoplatelets can be used to generate compositions as described herein. For instance, in some embodiments, appropriate quantities of a suspension of debundled carbon nanotubes in a solvent and a suspension of debundled graphite nanoplatelets in the same or other, but miscible, solvent containing the binder, can be mixed to form a single debundled suspension that is a D-TIM precursor. It should be appreciated that the suspensions can be prepared using any suitable technique, including methods known in the art. The solvent or solvents can be removed from the D-TIM precursor thus forming a D-TIM of desired composition and phase. In some embodiments, another method of obtaining a D-TIM involves milling (1) carbon nanotubes (for instance about 35% by weight), (2) crystalline carbon nanoplatelets such as graphite or/and graphene (for instance about 65% by weight) until a uniform dispersion is obtained. The mixture then can be consolidated into a D-TIM, for example, in the form of a tape with or without a binder. During compounding, covalent binding between the carbon nanotubes and carbon nanoplatelets may occur but this is not essential for obtaining a D-TIM having variable thermal conductivity as a function of temperature.

In some embodiments, dispersed CNTs are added to dispersed nGPs (e.g., GNPs) in the presence of one or more solvents. In some embodiments, solvents can be, but are not limited to, water, isopropanol, and their mixtures, with or without other alcohols added. In some embodiments, the addition of ammonia or amines aids in dispersion. Alternatively, dispersion can be achieved using hydrocarbon and related solvents. In some embodiments, the use of chlorinated solvents is strongly undesirable. In some embodiments, the acceptability of acetone depends on the purity of this solvent. The presence of acids, such as acetic, sulfuric or hydrochloric acid also can be detrimental and is avoided in some embodiments. The presence of crystallizing salts also can be detrimental and is avoided in some embodiments.

In some embodiments, it is possible to use a base medium such as for a thermal grease or phase-change material as the dispersion liquid base (This medium will be in a liquid phase at the temperature of the mixing process and the temperature during mixing can be elevated as necessary to keep the medium from freezing) as a dispersion liquid for making the intermediate dispersions A and B and then mixing these into the final dispersion C. Then dispersion C becomes a thermal grease or a phase-change material. This route to thermal grease or phase-change materials has been successfully tested with paraffins as the base media. The slope of the dependence of thermal conductivity on temperature was in limits exhibited by undiluted, cured D-TIM. The ambient temperature thermal conductivity was proportionally lower. An issue arose with thermal interface heat conduction. This issue can be abated by use of an additive such as small primary particle carbon black. (This is a generic use of carbon black in thermal pastes developed and reported by DLL Chang, see for instance Composite Materials: Science and Applications—Google Books Result books.google.com/books?isbn=1848828306 . . . Deborah D. L. Chung—2010). The formulation as a thermal adhesive can be obtained by this route by using a liquid base with adhesive properties. For thermal adhesives a post-application cure is envisioned. Such thermal adhesive is a prospective example.

In some embodiments, it is more effective for a cured D-TIM material to be dispersed in an appropriate medium to obtain thermal interface material in a desired form such as a thermal grease or a thermally conductive adhesive or a phase change material. It can also be possible to disperse green uncured D-TIM composite into some other media yielding a thermal interface product of a desired form.

In some embodiments, certain commonly used fillers in the thermal interface materials can be added to modify other specifications of the final product of interest. For example, particulate carbon black, or alumina have been tested, magnesia, and zinc oxide are being tested and preliminary results indicate they are compatible with the D-TIM function as thermally conductive medium with strongly temperature dependent thermal conductivity. Other particulate materials can be added as well according to the need of a user.

Curing Considerations:

In some embodiments, the structure of a composition is stabilized by curing. This can be useful to reduce the formation of aligned structures that may undermine the desired thermal conductivities. In some embodiments, curing can stabilize the physical properties of a TIM, for example to generate material that has reliable and reproducible thermal conductivities. Accordingly, curing can promote and maintain stable performance, including heat conduction, electrical conduction, and/or mechanical properties of a solid D-TIM, either self-standing or supported.

In some embodiments, curing can include a first step to remove liquid. In some embodiments, curing can include a second step to prevent reorganization of a dried product.

In some embodiments, a curing process involves heating composition for a sufficient time to generate a product that has reproducible properties (e.g., heat conductivity, electrical resistance, physical properties, or a combination thereof). In some embodiments, a D-TIM is heated to a temperature ranging from 80° C. to 120° C. until a constant electrical resistance is obtained. In some embodiments, curing can be accomplished with external heating by conductive or radiant heating or with Joule self-heating (electrical heating). However, it should be appreciated that for a reliable evaluation of the D-TIM curing process, the measurement of electrical resistance should be conducted under negligible Joule heating. In some embodiments, the cure is deemed complete if subsequent electrical resistance readings are the same within 0.125% when taken in sets of no less than five each at one hour apart.

It should be appreciated that excessive heat treatment should be avoided. In general, the binder may be more sensitive to heat treatment. However, elemental carbon also can be removed, especially at temperatures above 400° C., or in presence of oxidation catalysts, such as metal particles.

Curing can be performed before an application of the D-TIM composition-based material as a heat transfer medium. The product of the cure can be a self-standing material or a supported material. Supports can be in solid form (plates, films, porous materials such as woven, knits, mats or sponges). In some embodiments, the solid material can be a glass, graphite, glassy carbon, a metal, or a polymer or a semiconductor. In some embodiments, if the D-TIM layer is to be less than 10 microns thick, compatibility between the substrate and the material should be considered and possibly tested.

Accordingly, a TIM can be formed from a plurality of nanotubes such as multiwall carbon nanotubes (MWCNT) and nanoplatelets such as graphitic nanoparticles, which based on their unique properties and sizes increase the heat transport across the otherwise rough interface of mating surfaces. A temperature-dependent thermal conductivity is not theoretically predicted by the Green's function model of transport for low frequency phonons across tube-tube junctions [Chalopin, et al. Upper bound to the thermal conductivity of carbon nanotube pellets” J. Appl. Phys. 105, 084301 (2009)], and has not been otherwise experimentally observed above 50° C. Thermal conductivity of covalent junctions between carbon nanotubes has maximum near ambient temperature according to E. Pop, D. Mann, Q Wang, K. Goodson, H. Dai, Nano Letters, 6 (2006) 96.

According to aspects of the invention, the incorporation of CNTs (e.g., single or multi-walled) introduces a reversible modulation of the thermal conductivity of the composite relative to graphitic carbon alone. In some embodiments, relatively small CNTs are effective and can be used to produce strong thermal conductivities. This was unexpected, because smaller CNTs were not expected to work effectively since smaller CNTs were thought to reduce heat transfer by interrupting the phonon pathway. The phonon pathway requires physical contact. In contrast, without wishing to be limited by theory, compositions described herein provide an aggregate electronic structure that acts as an IR sink if/when excited and this is based on a near field effect. In some embodiments, excitation can occur at room temperature or below. In some embodiments, the near field effect can operate over micron-scale distances for compositions of the invention. In contrast, phonons act over much shorter distances (e.g., on the order of 10 nm).

While certain mixtures of individual or small bundles of CNTs (SWCNT, DWCNT, or MWCNT) and nGP (graphene, multilayer graphene, or graphite nanoplatelets) have been described, aspects of the prevent invention are based, at least in part, on the recognition of the benefits of dispersed preparations of relatively small nGPs and CNTs, including a surprising temperature-dependent thermal conductivity.

It was thought prior to the present disclosure that larger lateral diameters of nGP were more advantageous than shorter ones. It also was thought that longer CNT were more advantageous that the shorter ones. The rationale was based on the fact that in nanocarbon particles, a longer mean free path of charge propagation through C particle was obtained with larger lateral dimensions of nGP, and longer and defect-free CNTs.

However, according to aspects of the invention, the length the CNTs and/or lateral diameter of graphene and their crystalline perfection is a governing factor for effectiveness of heat transport when it proceeds mainly though phonon transport. This occurs when electrical percolation was just achieved in the composite. However, once there is significant side to side overlap, radiative near field energy transfer can become activated. Once a near-field mechanism is activated, the oscillations of charge carriers will significantly contribute to the heat transport and then the matching of oscillatory frequencies (for example, a nearly perfect match between CNT and graphene), the duration of orientation in position that enables coupling (a dynamic parameter), and the population of charge carriers will significantly contribute or dominate the heat transport instead.

In some embodiments, care should be taken to avoid unintentional alignment prior to or during curing. For example, unintentional alignment can occur by simply applying frictional motion to uncured dispersion deposited on a substrate. Alignment can also occur if electromagnetic field is applied to the dispersion before it is dried.

Defect Considerations:

According to aspects of the invention, in some embodiments the slope of the temperature dependence is related to the activation of mobility of ‘defects’ in the structure of the composite. One or more ‘defects can arise from i) mechanical damage such as grinding of the suspension of the dry components or the components in a solvent, ii) chemical damage such as oxidative cutting, and/or iii) radiative cutting, such as in form of nuclear radiation.

In some embodiments, open-ended CNTs are preferred to close ended CNTs (for example because they increase defects that can be mobilized in the interaction with the components of the composite).

Storage and Transport Considerations:

In some embodiments, a cured D-TIM composition is stable for years at ambient temperature in air. The stability of pastes depends on additives. Badly mixed (not adequately homogenized) pastes or more dilute dispersions coagulate. Coagulation can occur within seconds if the CNT is not adequately dispersed. Coagulation at present is viewed as detrimental, however it is not known if the coagulated product loses the desired thermal properties, simply because it is hard to form into a contiguous solid in a size suitable for current testing methods. Homogeneous mixing is beneficial, so dispersions A and B must be stable, but the stability of the dispersion C is probably a matter of uniformity of the product followed by a matter of convenience.

Metal Considerations:

In some embodiments, the presence of large metal particles (e.g., large Ag particles) may reduce or eliminate the temperature-dependence of thermal conductivity for a composition described herein. For example, metal particles larger than 10 nanometers on average are undesirable in some embodiments. This also applies to transition metals used as catalysts in the synthesis of nanocarbon substrates for the D-TIM. In some embodiments, these particles are restricted to less than 0.1% or less than 0.05% of the formulation by weight. In some embodiments, the same metal particles larger than 100 nm are less desirable, because their surface will decrease in proportion to their size. In some embodiments, they should be present at less than 0.1% or less than 0.05% of the formulation by weight. Similarly, larger particles, e.g., metal particles larger than 1 micron, are less desirable, and they also should be present at less than 0.1% or less than 0.05% of the formulation by weight.

Accordingly, in some embodiments compositions described herein are substantially metal-free or substantially free of large metal particles (e.g., free of particles of silver or Ag, copper, gold, iron, cobalt, nickel, cadmium, molybdenum, vanadium, iridium, rhodium, palladium, platinum, and their metallic coatings on other particulate materials).

Density Considerations:

It should be appreciated that compositions of the invention may be produced with different densities. For example, D-TIM paper can be produced at different densities. It should be appreciated that the density is limited by the concentration weighted sum of densities of the components of the D-TIM. If the D-TIM composition is restricted to the CNT, nGP and a binder, the density of the resultant D-TIM by nature cannot be higher than the density of crystalline graphite. If by processing one obtains a porous D-TIM, the apparent density of such material will be still lower. The lowering of the density is related to the presence of pores (interstitial spaces) in the material. The pores in D-TIM should not be large. In some embodiments, the pores in D-TIM are no wider than 1 micron on average. In some embodiments, the pores in D-TIM are no wider than 15 nm on average.

In some embodiments, the density of a composition described herein (e.g., a cured composition) is lower than that of crystalline graphite. The density of crystalline graphite is about 2.25 g/cm3, and this is the natural limit. The densities of graphite compacts for lateral heat transfer applications approach the density of graphite, and are in range of 1.7 to 2.1 g/cm3 (note that these are high densities and may not be effective if they are obtained by means that preclude the mutual alignment of nGP particles). These composites, for example, from Amec-Termasol have anisotropic thermal conductivity that is high in the lateral direction and about 16 W/m·K in the direction perpendicular to the carbon plane.

In contrast, compositions of the invention typically have lower densities. In some embodiments, they are similar to densities of graphite foils. Graphite foils are lighter due to large interstitial spaces. For example, commercial soft graphite foils used for gaskets have apparent densities on the order of about 0.5 to 1 g/cm3.

In some embodiments, compositions of the invention have densities that range from about 0.1 to about 1.75, for example from about 0.3 to about 1.5, or about 0.5 to 1, or about 0.9 g/cm3.

In some embodiments, the composition of a D-TIM is such that the molecular motions are very strongly restricted. In some embodiments, the composites of higher density have higher base thermal conductivity that the composites of lower density. In some embodiments, composites with an apparent density about 0.9 g/(cm3 have thermal conductivity, κ, at ambient T above 100 W/m·K, but a maximum in κ appears at about 180° C. This is thought to be related to the ‘empty space content’ in the composite. It depends on both the composition and the method of preparing the composite. There will be some compositions that will be more amenable to self-organizing themselves into the composite with a desired property depending on the proportions of the dimensions.

Accordingly, in view of the summary and detailed description above, it should be appreciated that in some embodiments, aspects of the invention relate to a thermal interface composition comprising carbon nanotubes, and nano-graphite particles, wherein the carbon nanotubes are dispersed among the nano-graphite particles and the composition demonstrates a positive thermal dependence of thermal conductivity. In some embodiments, the nano-graphite particles are graphene or graphite nanoplatelets. In some embodiments, the average lateral dimension of the nanoplatelets is less than 1 micron, for example less than 0.5 micron, or about 0.3 micron. In some embodiments, the average thickness of the nanoplatelets is at least 10 times smaller than average lateral diameter of the nanoplatelets. In some embodiments, the average length of the nanotubes is less than 30 times the average lateral dimension of the nanoplatelets, for example about 20 times the average lateral dimension of the nanoplatelets, less than 20 times the average lateral dimension of the nanoplatelets, less than 10 times the average lateral dimension of the nanoplatelets, or about 5 times the average lateral dimension of the nanoplatelets.

In some embodiments, the nanotubes are multi-walled. In some embodiments, the nanotubes are single-walled. In some embodiments, the average length of the nanotubes is greater than 10 times their outer diameter. In some embodiments, the average length of the nanotubes is 3-50 microns, 10-20 microns, 2-10 microns, 3-5 microns, or 0.5 to 2 microns. In some embodiments, the average outer diameter of the nanotubes is 5-25 nm, 8-15 nm, 5-25 nm, or about 10 nm.

In some embodiments, the mass ratio of nanoplatelets to nanotubes is between 10:1 and 1:1, for example, about 2:1. In some embodiments, the density of the composition is from about 0.1 to about 1.75 g/cm³, from about 0.3 to about 1.5 g/cm³, from about 0.5 to about 1 g/cm³, for example about 0.9 g/cm³. In some embodiments, at least 40% (for example, at least 60%, or at least 70%, or at least 80% or more) of the mass of the composition is due to crystalline carbon nanoparticles. In some embodiments, the crystalline carbon nanoparticles comprise CNTs ranging from 20% to 80% by weight, and graphite or graphene nano-platelets ranging from 20% to 80% by weight. In some embodiments, the crystalline nanoparticles consist of CNTs ranging from 30% to 55% by weight, and graphene or graphite nano-platelets up to 70% by weight.

In some embodiments, a composition further comprises a binder that promotes a positive temperature-dependent thermal conductivity. In some embodiments, the binder is selected from cellulose based polymers, polyamides, poly alcohols, acrylates, polynitriles, poly-olefins, polyesters, polycarbonates, some thermoplastics, or thermosets, and/or elastomers provided the thermal coefficient of electrical resistance remains negative.

In some embodiments, aspects of the invention relate to a method for promoting heat transfer from a first surface, the method comprising contacting the first surface with a composition described herein. In some embodiments, the first surface is the surface of a computer component. In some embodiments, the computer component surface is selected from semiconductors, alumina, magnesia, silica, silicon, and silicon carbide based ceramic, copper, or gold or nickel, or polymer metal laminates. In some embodiments, the first surface is the surface of a power generating component. In some embodiments, the power generating component is selected from solar power collecting devices, wind turbines, hydroelectric turbines or heat turbines or engines. In some embodiments, the power converting component is selected from photovoltaic devices, light emitting diodes, power converters, e.g., direct current inverters, radiofrequency emitters, ultrasound emitters, heat pipes and any other devices exhibiting heat loads of 10 W/cm2 or higher. It should be appreciated that a composition of the invention can transfer the heat to a second surface that is in contact with the thermal interface material (e.g., on the other side from the first surface) and/or to another medium (e.g., air, gas, or liquid) or a combination thereof.

In some embodiments, aspects of the invention relate to a computer component or a power generating component comprising a composition described herein in contact with at least one surface. In some embodiments, aspects of the invention relate to a computer or other device that comprises one or more elements coated with a thermal interface material described herein.

In some embodiments, a thermal interface composition is cured. In some embodiments, the composition is a solid. In some embodiments, the composition is viscous or malleable. In some embodiments, the composition is a self-standing material, a supported material, a backed material, or a coated material. In some embodiments, supported material is supported on a sheet. In some embodiments, the material is backed by one or more adhesive coatings or coated with a thermal interface resistance decreasing coating. In some embodiments, the thermal interface resistance decreasing coating is a coating with a small particle size (e.g., about or below a 50 micron primary particle size, low structure, high crystallinity carbon black, etc.). In some embodiments, the sheet is a sheet or film or paper, or a mat or carpet made of material selected from cellulose based polymers, polyamides, poly alcohols, acrylates, polynitriles, poly-olefins, polyesters, polycarbonates, rubbers, elemental carbon, graphite, silicon, silicon nitride, some thermoplastics, or thermosets, and/or elastomers provided the thermal coefficient of electrical resistance remains negative. In some embodiments, the sheet also can be made from one or more metals. In some embodiments, one or more dimensions (e.g., one or more lateral dimensions such as width or length) of the composition can range from 0.1 micron to 100 microns, to 1 cm, to 10 cm, to 100 cm, or higher or lower. It should be appreciated that the material can be formed in any suitable shape. In some embodiments, it may be square, rectangular, round, oval or other geometric shape. However, it also may have a complex or irregular shape (including, for example, having one or more perforations) as aspects of the invention are not limited in this respect. In some embodiments, the thickness of the material ranges from a 25 micron film to a several mm thick sheet (e.g., a 2 mm thick sheet, or thicker). In some embodiments, the lateral dimensions are from 1 cm to 20 cm or greater. For example, the supported films could from 1 cm up to 20 cm wide and significantly longer (e.g., from 100s of cms to meters or longer, for example continuous in length, for example in the form of a roll).

In some embodiments, aspects of the invention relate to methods of making a composition described herein by dispersing carbon nanotubes within nanographite particles to form a homogeneous mixture.

In some embodiments, aspects of the invention relate to a combination of multiple-walled carbon nanotubes (MWNTs) that have 2 or more concentric walls and graphite nanoplatelets that endow the nanocomposite with thermal conductivity reversibly and usefully increasing with temperature. In some embodiments, a small amount of polymeric component (below 30 wt. %) serves as a binder, significantly improving the integrity of the carbon matrix. Both ambient thermal conductivity and the rate of change of the thermal conductivity with temperature are improved with curing by a heating process. The direction and rate of change of the thermal conductivity with temperature is improved in the composite of multiple-walled carbon nanotubes and graphite nanoplatelets compared with comparable amounts of either nanographite or MWNTs-modified polymer nanocomposites. Many polymers may work as binders for the composite of multiple-walled carbon nanotubes and graphite nanoplatelets. Besides thermoplastic, thermoset, and other polymers may also work.

Aspects of the invention may be used as thermal interface materials for a variety of applications. For example, thermal interface materials may be used in connection with one or more of the applications described in the disclosures of U.S. patent application Ser. No. 11/419,235, filed on May 19, 2006, published as US 2007/0267602; Ser. No. 09/958,032, filed Oct. 3, 2001, published as US 2002/0158236; Ser. No. 12/321,568, filed Jan. 22, 2009, published as US 2009/0197082; Ser. No. 12/524,502, filed Nov. 12, 2009, published as US 2010-0084598; Ser. No. 11/910,963, filed Oct. 8, 2007, published as US 2009/0121183; Ser. No. 12/270,171, filed Nov. 13, 2008, published as US 2009/0072196; Ser. No. 11/766,904, filed Jun. 22, 2007, published as US 2007/0295941; Ser. No. 11/385,453, filed Mar. 21, 2006, published as US 2007/0221879; Ser. No. 12/516,182, filed Jul. 10, 2009, published as US 2010/0051879; Ser. No. 09/848,687, filed May 3, 2001, published as US 2002/0063233; Ser. No. 10/580,025, filed May 19, 2006, published as US 2009/0039314, patented as U.S. Pat. No. 7,841,390; Ser. No. 11/765,946, filed Jun. 20, 2007, published as US 2008/0093577, patented as U.S. Pat. No. 7,998,367; and Ser. No. 10/663,152, filed Sep. 15, 2003, published as US 2004/0051433, patented as U.S. Pat. No. 6,825,610, all of which are incorporated herein by reference in their entirety.

The working temperature range of a device is a part-specific relevant attribute; factors such as the thermal stack size, shape, orientation, material composition, and surface finishes are subject to the design of the thermal management system. For power electronics and machinery the gaps (e.g., the gaps between the hot part and the thermal management hardware) are on the order of 100 microns. Such gaps are categorized as large. Materials typically facing a TIM in a large gap can be a type of steel, or aluminum, copper, titanium, or alumina ceramic, silica or glass, or polymers, less often molybdenum disulfide, silicon carbide or silicon. Smaller electronic devices have gaps with distances between the stack's components in range from 5 μm to 80 μm, but more commonly now only to 20 μm, with 5 microns as a minimum for board-level device reliability. Gaps of 50 microns and smaller are categorized as small. Such gaps are common in computing electronics. The materials most commonly facing a TIM in a small gap is a polymer, silica, and/or silicon or other semiconducting materials, silicon carbide, alumina ceramic on one side, and aluminum, copper, other metals, alumina and other ceramics, silica or glass. It is the width of the gap that has primary impact on specifications of the thermal interface materials. The bulk thermal conductivity and coefficient of thermal expansion, CTE, are the primary criteria for selection of the TIM. These parameters remain important for small gaps, but thermal interface resistance becomes dominant over bulk thermal conductivity. In some embodiments, D-TIMs described herein can be used to provide a thermal interface between any of these components across small or large gaps.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed.

These and other aspects of the invention are illustrated by the following non-limiting Examples and Claims.

### EXAMPLES

### Example 1

### Thermal Conductivity Changes as a Function of Temperature

A mixture was prepared of 1 (one) part by weight of short (2 μm on average) and thin (8 to 15 nm outer diameter) multiple walled carbon nanotubes with 2 (two) parts by weight of nanographite platelets with 0.3 μm on average lateral diameter, and at least ten times smaller average thickness.

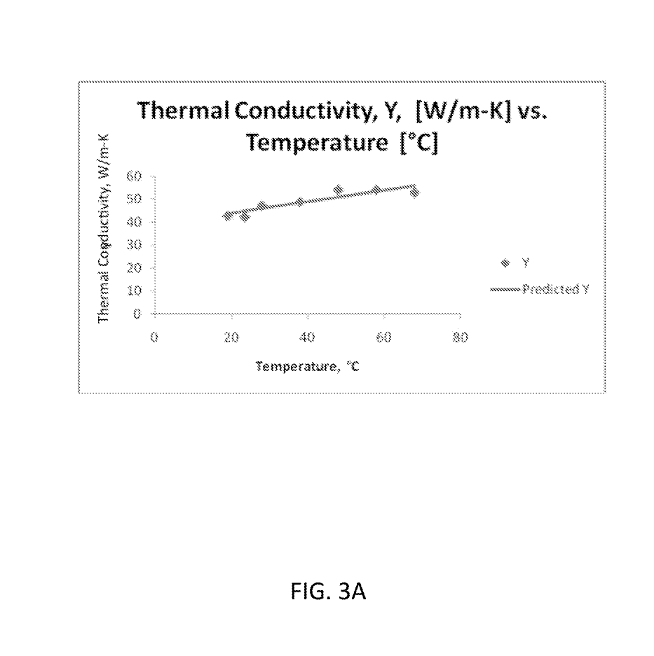

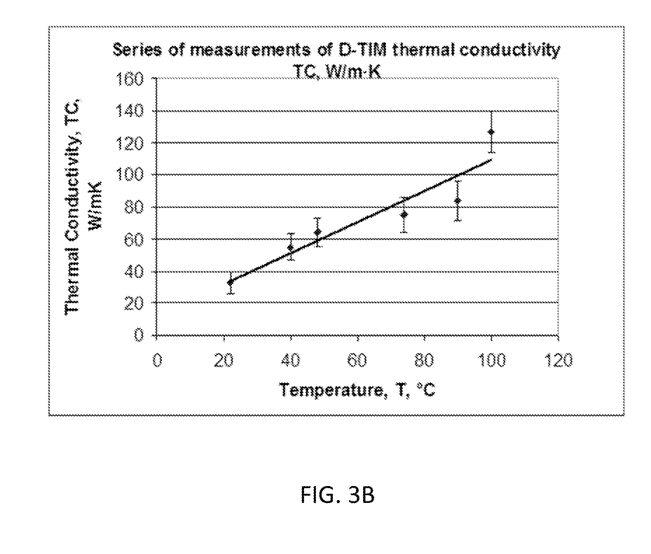

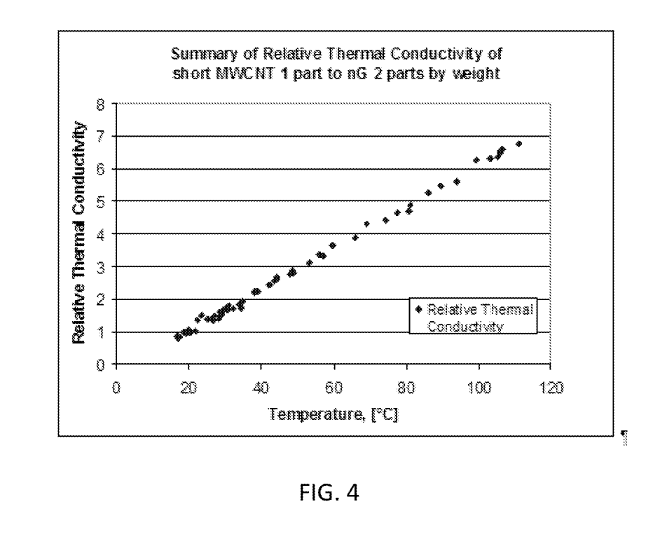

The thermal conductivity change was measured as a function of temperature. Results for a first composition are shown in FIG. 3. Measurements were repeated for further D-TIM samples having a 1:2 by weight MWCNT: nG mix, and the results are shown in FIG. 4.

In one example, the following material composition was used: 95 to 98% elemental carbon by weight in that SMW 20×-L3 34% by weight, 66% graphite by weight such as for electron microscopy conductive paints, and 3% polymeric binders (polyacrylate). The resultant apparent density was 0.85 g/cm3 as a self-standing material after ambient cure. This was not measured after the thermal cure, but is not expected to increase. The electrical bulk resistivity was 0.00126 Ω·m at 25° C. after ambient cure in air for 96 hours, decreasing to 0.0006 Ω·m at 25° C. after thermal/electrical cure at 180° C.

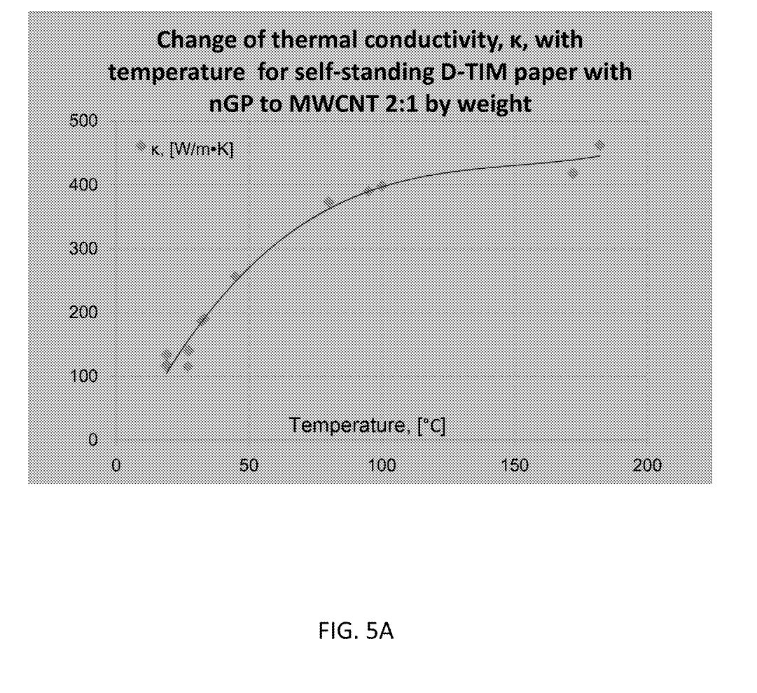

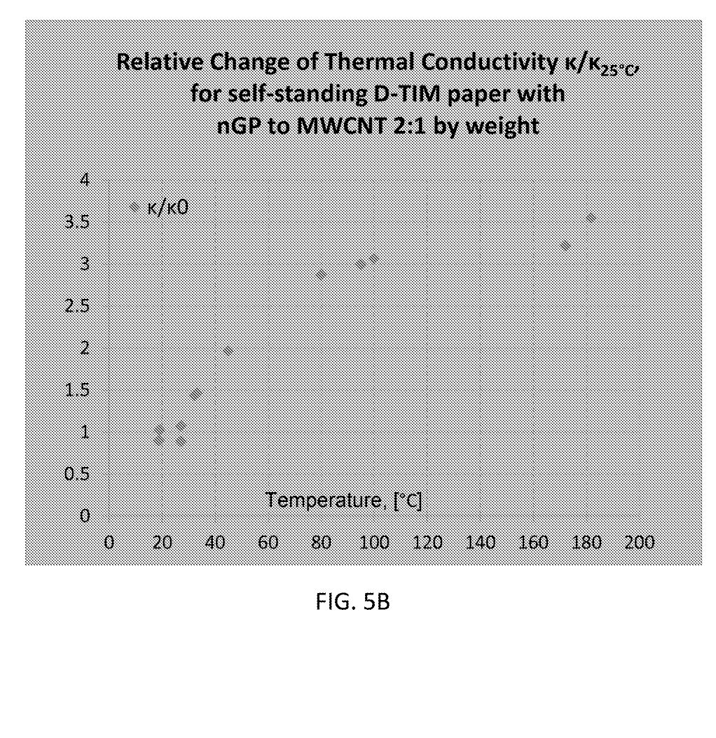

The thermal conductivity of this material in a paper form as a function of temperature is shown in FIG. 5.

An example of a composition having an nGP0.66 MWCNT(1-0.66) mix shows ambient thermal conductivity κ=30±4 W/m·K (see FIGS. 3A and 3B) while the commercial TIMs have κ<10 W/m·K (using an MWCNT substrate from Cheap tubes). Using MWCNTs from SWeNT type SWE200x yielded ambient bulk thermal conductivity of 110 to 130 W/m·K in the mix nGP0.66 MWCNT(1-0.66) see FIG. 5). Variable temperature tests on this composition show that the thermal conductivity of the functional material is reversibly temperature dependent with the positive slope about 1 W/mK2.

It should be appreciated that known assays may be used for measuring thermal conductivity. For example, a static electrical method of measuring thermal conductivity was used. The method applies to materials with electrical conductivity dependent on temperature with thermal coefficient of electrical resistance absolute value at or larger than 0.005. The slope for thermal conductivity of the D-TIM for a sample like the one presented in FIG. 3A was confirmed by independent measurement using an ASTM 5470 method.

### Example 2

### Methods of Preparing a D-TIM Nanocomposite

Material Composition:

A nanocomposite material was prepared to have the following composition: 3% polyacrylate binder by weight and 97% elemental carbon allotropes by weight, the carbons being: MWCNT 10±1 nm OD, 3 to 5 micron length at 34% by weight, and 66% graphite nanoplatelets: average lateral diameter 0.3 micron, average thickness below 30 nm. The material was assembled by a non-limiting mixing procedure that involves the following steps.

Mixing Procedure:

Step 1: Obtain a homogenous dispersion of a binder with graphite of appropriate dimensions in a solvent, e.g., isopropanol. This is dispersion A. Dispersion A can have a concentration of up to 25 weight percent of graphite in a solvent. Dispersion A can also contain up to 10% binder. The solvent can be a single chemical or a mix of liquid chemical species. The dispersion is a generic process resulting in a homogeneous mixture, such that 90% of particles pass through 0.5 micron filter or equivalent test.

Note that the binder fraction will decrease down to the final content upon completion of step 3.

Step 2: Obtain a homogenous dispersion of MWCNT of appropriate dimensions, for example, using the same solvent as in step 1, e.g., isopropanol. The dispersion is a generic process resulting in a homogeneous mixture, such that no sedimentation occurs upon standing still for a minimum of an hour, or an equivalent test. This is dispersion B. Dispersion B can have a concentration of up to 25 weight percent of MWCNT in the solvent.

Step 3: Add dispersion B into dispersion A drop-wise while homogenizing the resulting mixture using ultrasound and/or mechanical mixing. Step 3 generates a homogenous dispersion of the D-TIM in a solvent. In some embodiments, homogenous means that 90% of agglomerates, if any, pass 10 micron filter. In some embodiments, the dispersion is evaluated using a stability test, for example a dispersion can pass a stability test if no precipitation of solids occurs upon standing still for a minimum of an hour, or an equivalent test. This is dispersion C. It should be appreciated that at this step one can control the ratio of MWCNT to graphite nanoplatelets. The amount of binder is controlled by design of dispersion A and design of proportion of mixing of dispersion A and dispersion B.

Step 4: Deposit dispersion C on a substrate and allow it to air-dry to form a solid layer. Repeat the application and drying as needed to build up the thickness of the solid layer. Upon final drying a self-standing film forms. This is green D-TIM. Note that this uncured product is re-dispersible in the original solvent, e.g., isopropanol, and/or other solvents. Accordingly, the layer of D-TIM can be re-dissolved and re-applied. The application can be performed by any generic method, such as casting, painting, screen printing, gravure, Mayer rod coating, knife coating or gravure, or other coating procedure (e.g., a generic coating procedure). If necessary, viscosity adjustments can be made by design regulating the amount of solvent in steps 1 and 2 for this purpose, or ad-hock by diluting and homogenizing dispersion C.

Step 5: Cure the green D-TIM by subjecting it to heat (e.g., self-generated such as electrical Joule heating, and/or radiant, conductive, or convective heating) of sufficient temperature and duration such that upon cooling to about 25° C. stable electrical conductivity is achieved under conditions of negligible Joule heating in still air (the material does not heat up during the measurement). The resultant product is a D-TIM. It should be appreciated that cured product, the D-TIM, is still dispersible in the original solvent, e.g., isopropanol, and/or other solvents. Accordingly, the layer of D-TIM can be re-dissolved and re-applied. The application can be performed by any suitable generic method. In some embodiments, reapplied material may require a repeat of the thermal cure, for example, if the solvent for the re-dispersion was not aprotic.

In some embodiments, denser material can be obtained through multiple repetitions of step 4, for example using a suspension containing up to 10% solids. The use of a single deposition of a more concentrated suspension results in a less dense D-TIM. In some embodiments, the less dense material has lower base conductivities than the more dense material, and a lower slope of the thermal conductivity as a function of temperature.

Preparation of D-TIM Material for Tests Shown in FIGS. 5-7:

The following compositions were prepared:

1. Control nGP on PE plain and stretched

2. Test sample of 2nGP+1 MWCNT from SWENT—stretched

3. Bucky paper 60 micron thick, having a resistance of 60 ohms on a piece with dimensions of 7 mm by 20 mm, resistivity 0.00126 Ω·m at 25° C. before thermal cure, 0.0006 Ω·m at 25° C. after a combination thermal and electrical cure (180° C. for about 15 minutes), density: mass determined as a difference of a weighing boat with and without of the test material: 0.0584 g−0.0440 g=0.0144 g corresponds to 2.8 cm long by 1 cm wide piece 60 micron thick, volume 0.0000000168 m3, (0.0168 cm3) corresponding to 0.857 g/cm3 density. The paper is fairly stiff and brittle, but was successfully contacted with alligator clips. For comparison, the commercial carbon nanotube buckypaper has a resistivity of ˜10 Ω·m see http://www.nano-lab.com/buckypaper.html. Accordingly, compositions produced using methods described herein have very high electrical resistivity.

Preparation Materials:

The nG and MWCNT were prepared to obtain a 2:1 ratio (0.1932 g of 20% of graphite dispersion and 0.0966 g CNT):

Mixing Procedure:

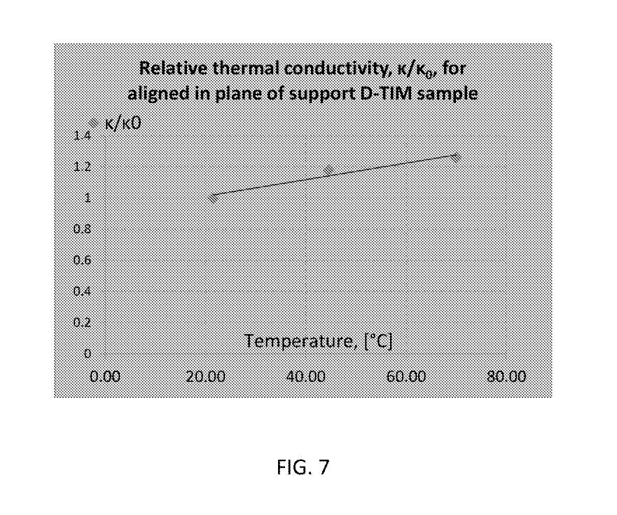

The CNT was introduced into the nGP paint mixed in mortar by hand, allowed to almost dry, diluted with 91% isopropanol-water mixed 50:50 by volume with 10% ammonia, sonicated for 10 minutes, ground in the mortar to near dryness, treated with 91% isopropanol-water 50:50 with 10% ammonia again, then painted on PE. PE was stretched while the coating was drying. The product was cured after drying and the electrical and thermal conductivity was measured. The results are shown in FIG. 7. The rest of the material was divided in two portions, one portion was allowed to dry and form a ‘bucky paper’ and the electrical and thermal conductivity of this paper was tested. The results are shown in FIG. 5.

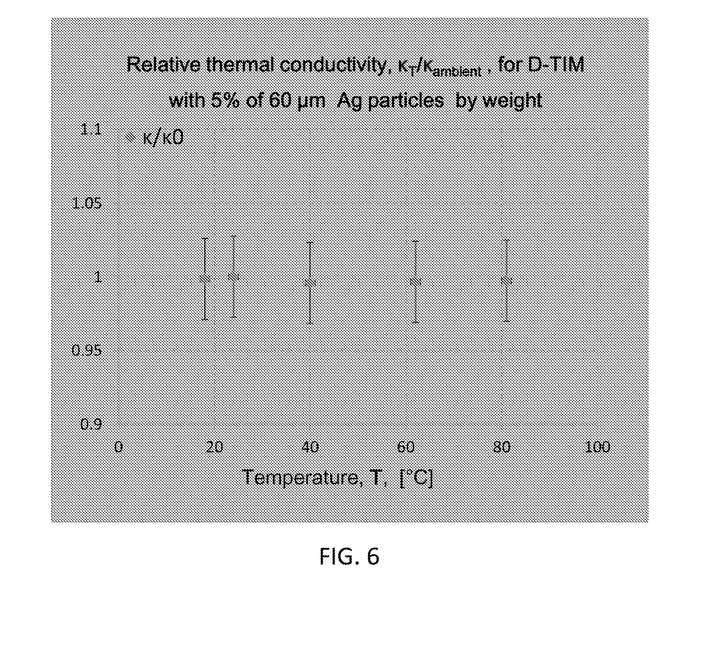

The other portion was mixed with a dispersion of silver particles (e.g., about 60 microns in size and about 5% of the specimen mass). The mixture was allowed to dry and form a silver-doped ‘bucky paper’ and then cured. Then electrical and thermal conductivity was then tested. The results are shown in FIG. 6.

### Example 3

### Impact of Metal on Thermal Conductivity

A D-TIM was prepared with 66% nGP (obtained from SPI)+34% MWCNT (obtained from SWeNT)+10% Ag paint added. Relative thermal conductivities were measured in a temperature range of 18° C. to 82° C. The results shown in FIG. 6 indicate that no significant temperature dependence of thermal conductivity is found in the presence of Ag metal particles.

### Example 4

### The Impact of Particle Alignment

Experiments were performed to test the effect of the alignment of carbon particles by aligning compositions of the invention. A film supported by a polyethylene (PE) was used. The film was stretched while the dispersion was drying on the PE surface, then air dried and cured at 80° C. to constant electrical resistance. The layer of the dispersion can also be aligned this way by rubbing the drying the dispersion gently. However, the stretching is easier to apply without damage to the continuity of the drying sample. Stretching aligns the graphite nanoplatelets so that they overlap like shingles on a roof, or scales on a fish. FIG. 7 shows the resulting thermal conductivity in the direction of the stretching. This illustrates a significant decrease of the slope of the thermal conductivity from a factor of about 3 over the temperature span tested to about only a 25% increase.

It should be appreciated that in some embodiments aligned carbon particles (e.g., aligned through stretching or other technique) can be identified due to a visible signature. For example, in some embodiments an aligned sample acquires a metallic sheen, whereas an unaligned sample does not reflect visible light, even of high intensity. Accordingly, this difference can be visualized by flash versus ambient illumination photographs

### Example 5

### Alternatives to Carbon-Based Particles

A D-TIM may be based on a nanocomposite system containing other nanoplatelets combined with nanotubes, e.g., boron nitride. For example, in some embodiments carbon may be substituted (e.g., in the nanotubes and/or nanoplates) with one or more of the following elements: nitrogen, boron, silicon, sulfur, phosphorus, rare gasses such as Argon krypton or xenon, or any combination thereof. In some embodiments, carbon nanotubes and/or graphitic nanoplatelets decorated on open edges with hydroxyl, carbonyl, epoxy, and/or carboxyl groups, and/or nitryl, amino, and/or phosphin groups. In some embodiments using these alternative elements, similar size and ratios of nanotubes and nanoplatelets are used as for the carbon-based compositions in order to generate the desired properties and to interface with the surface properties (e.g., roughness) of electrical or semiconductor components (e.g., in stacks).

1. A thermal interface composition comprising:
carbon nanotubes, and
nano-graphite particles,
wherein the carbon nanotubes are dispersed among the nano-graphite particles and the composition demonstrates a positive thermal dependence of thermal conductivity.

2. The composition of claim 1, wherein the nano-graphite particles are graphene or graphite nanoplatelets.

3. The composition of claim 1, wherein the average lateral dimension of the nanoplatelets is less than 1 micron.

4-5. (canceled)

6. The composition of claim 1, wherein the average thickness of the nanoplatelets is at least 10 times smaller than average lateral diameter of the nanoplatelets.

7. The composition of claim 1, wherein the average length of the nanotubes is less than 30 times the average lateral dimension of the nanoplatelets.

8-33. (canceled)

34. A method for promoting heat transfer from a first surface, the method comprising contacting the first surface with a composition of claim 1.

35. The method of claim 34, wherein the first surface is the surface of a computer component.

36. The method of claim 35, wherein the computer component surface is selected from semiconductors, alumina, magnesia, silica, silicon, and silicon carbide based ceramic, copper, or gold or nickel, or polymer metal laminates.

37. The method of claim 34, wherein the first surface is the surface of a power generating component.

38. The method of claim 37, wherein the power generating component is selected from solar power collecting devices, wind turbines, hydroelectric turbines or heat turbines or engines.

39. (canceled)

40. A computer component comprising a composition of claim 1 in contact with at least one surface.

41. A power generating component comprising a composition of claim 1 in contact with at least one surface.

42-53. (canceled)
